(19) United States
(12) Patent Application Publication
(10) Pub. No.: US 2024/0363750 A1
(43) Pub. Date: Oct. 31, 2024

(54) SEMICONDUCTOR DEVICE INCLUDING FIELD EFFECT TRANSISTOR FORMED ON SOI SUBSTRATE

(71) Applicant: Renesas Electronics Corporation, Tokyo (JP)

(72) Inventors: Kazuya UEJIMA, Tokyo (JP); Shiro KAMOHARA, Tokyo (JP); Michio ONDA, Tokyo (JP); Takashi HASE, Tokyo (JP); Tatsuo NISHINO, Tokyo (JP)

(21) Appl. No.: 18/771,200

(22) Filed: Jul. 12, 2024

Related U.S. Application Data
(63) Continuation of application No. 17/897,844, filed on Aug. 29, 2022.
Application No. 17/897,844 is a continuation of application No. 16/753,949, filed on Apr. 6, 2020, now abandoned.

(51) Int. Cl. H01L 29/78; H01L 27/12; H01L 29/06; H01L 29/10; H01L 29/423; H01L 29/45; H01L 29/51; H03F 3/45

(52) U.S. Cl. CPC H01L 29/7838; H01L 27/1203; H01L 29/0649; H01L 29/1083; H01L 29/42376; H01L 29/45; H01L 29/517; H03F 3/45179

(57) ABSTRACT

In a semiconductor device according to an embodiment, a thickness of a semiconductor layer of an SOI substrate on which a field effect transistor constituting an analog circuit is formed is set to 2 nm or more and 24 nm or less.

### CROSS REFERENCE TO RELATED APPLICATION

This application is a Continuation of U.S. patent application Ser. No. 17/897,844 filed on Aug. 29, 2022, which is a Continuation of U.S. patent application Ser. No. 16/753,949 filed on Apr. 6, 2020, which is the U.S. National Phase under 35 U.S.C. § 371 of International Application No. PCT/JP2017/040912, filed on Nov. 14, 2017, the entire contents are hereby incorporated by reference.

### TECHNICAL FIELD

The present invention relates to a semiconductor device, and relates to, for example, a technology effectively applied to a semiconductor device including a field effect transistor formed on an SOI (Silicon On Insulator) substrate.

### BACKGROUND ART

Japanese Patent Application Laid-Open Publication No. 2009-135140 (Patent Document 1) describes a technology for achieving both a high-speed operation of a logic circuit including a first field effect transistor formed on an SOI substrate and a stable operation of a memory circuit including a second field effect transistor formed on the SOI substrate.

Japanese Patent Application Laid-Open Publication No. 2013-84766 (Patent Document 2) describes a technology relating to a semiconductor device in which a first field effect transistor formed in an SOI region and a second field effect transistor formed in a bulk region are mixedly present.

Japanese Patent Application Laid-Open Publication No. 2013-219181 (Patent Document 3) describes a technology relating to a semiconductor device in which a first field effect transistor formed in an SOI region and a second field effect transistor formed in a bulk region are mixedly present.

Japanese Patent Application Laid-Open Publication No. 2016-18936 (Patent Document 4) describes a technology of using a high dielectric constant film as a gate insulating film of a field effect transistor formed on an SOI substrate.

Japanese Patent Application Laid-Open Publication No. 2012-29155 (Patent Document 5) describes a technology for forming an analog circuit and a digital circuit on an SOI substrate.

### RELATED ART DOCUMENTS

### Patent Documents

Patent Document 1: Japanese Patent Application Laid-Open Publication No. 2009-135140
Patent Document 2: Japanese Patent Application Laid-Open Publication No. 2013-84766
Patent Document 3: Japanese Patent Application Laid-Open Publication No. 2013-219181
Patent Document 4: Japanese Patent Application Laid-Open Publication No. 2016-18936
Patent Document 5: Japanese Patent Application Laid-Open Publication No. 2012-29155

### SUMMARY OF THE INVENTION

### Problems to be Solved by the Invention

For example, in order to reduce the power consumption of a semiconductor device, it is effective to reduce a driving voltage of a field effect transistor constituting the semiconductor device. Here, in order to reduce the driving voltage of the field effect transistor, it is said to be effective to use a so-called “thin BOX-SOI (SOTB: Silicon On Thin Buried Oxide) technology”. On the other hand, a semiconductor device includes a digital circuit, an analog circuit, and the like. Further, the study by the inventors of the present invention has revealed that various ingenuities are required for the structure, the way to use, and the like in order to improve the characteristics of the field effect transistor constituting the analog circuit particularly when the “SOTB technology” is used for the analog circuit.

Other problems and novel features will be apparent from the description of this specification and the accompanying drawings.

### Means for Solving the Problems

In a semiconductor device according to one embodiment, a thickness of a semiconductor layer of an SOI substrate on which a field effect transistor constituting an analog circuit is formed is set to 2 nm or more and 24 nm or less.

### Effects of the Invention

According to one embodiment, power consumption of a semiconductor device can be reduced while improving characteristics of the semiconductor device.

### BRIEF DESCRIPTIONS OF THE DRAWINGS

FIG. 1 is a diagram showing an example of an analog amplifier circuit using a field effect transistor and a constant current source;

FIG. 2 is a diagram illustrating that a gain (amplification factor) of the analog amplifier circuit shown in FIG. 1 depends on saturation characteristics of the field effect transistor;

FIG. 3 is a diagram illustrating that a gain (amplification factor) of the analog amplifier circuit shown in FIG. 1 depends on saturation characteristics of the field effect transistor;

FIG. 4 is a diagram illustrating a mechanism in which deterioration of saturation characteristics of a field effect transistor is less likely to occur when a field effect transistor having a gate electrode with a large gate length is formed on a thick semiconductor layer formed on a buried insulating layer;

FIG. 5 is a diagram illustrating a mechanism in which deterioration of saturation characteristics occurs when a field effect transistor having a gate electrode with a small gate length is formed on a thick semiconductor layer formed on a buried insulating layer;

FIG. 6 is a diagram illustrating a mechanism in which deterioration of saturation characteristics is less likely to occur when a field effect transistor is formed on a thin semiconductor layer formed on a buried insulating layer;

FIG. 7 is a schematic cross-sectional view showing a device structure of a semiconductor device according to a first embodiment;

FIG. 8(a) is a graph showing a relationship between a drain voltage and a drain current when a field effect transistor having a gate electrode with a gate length of 60 nm is formed on a bulk substrate;

FIG. 8(b) is a graph showing a relationship between a drain voltage and a drain current when a field effect transistor having a gate electrode with a gate length of 60 nm is formed on an SOI substrate having a semiconductor layer with a thickness of 24 nm;

FIG. 8(c) is a graph showing a relationship between a drain voltage and a drain current when a field effect transistor having a gate electrode with a gate length of 60 nm is formed on an SOI substrate having a semiconductor layer with a thickness of 12 nm;

FIG. 9(a) is a circuit diagram in which specific voltages applied to the analog amplifier circuit described in FIG. 1 when the analog amplifier circuit is driven at low voltage are written;

FIG. 9(b) is a graph showing a relationship between the gate length of the gate electrode of the field effect transistor and the gain in the analog amplifier circuit shown in FIG. 9(a);

FIG. 10(a) is a circuit diagram in which specific voltages applied to the analog amplifier circuit described in FIG. 1 when the analog amplifier circuit is driven at higher voltage than the operation condition of FIG. 9(a) are written;

FIG. 10(b) is a graph showing a relationship between the gate length of the gate electrode of the field effect transistor and the gain in the analog amplifier circuit shown in FIG. 10(a);

FIG. 11 is a diagram schematically showing a function and a circuit configuration of a differential amplifier;

FIG. 12 is a cross-sectional view showing device structures of a plurality of field effect transistors according to a second embodiment; and

FIG. 13 is a circuit block diagram showing a circuit configuration of a successive approximation A/D converter.

### DETAILED DESCRIPTION OF PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification, details, or a supplementary explanation thereof.

Also, in the embodiments described below, when mentioning the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, in the embodiments described below, it goes without saying that the components (including element steps) are not always indispensable unless otherwise stated or except the case where the components are apparently indispensable in principle.

Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Also, components having the same function are denoted by the same reference characters in principle throughout the drawings for describing the embodiments, and the repetitive description thereof is omitted. Note that hatching is used even in a plan view so as to make the drawings easy to see.

### First Embodiment

### <Usefulness of SOI Technology>

From the viewpoint of reducing the manufacturing cost of a semiconductor device, it is desired to increase the number semiconductor obtained chips from one of semiconductor wafer, and in order to increase the number of semiconductor chips obtained from one semiconductor wafer, field effect transistors have been miniaturized. Further, for the miniaturization of the field effect transistor, the reduction in the driving voltage (drain voltage and gate voltage) of the field effect transistor needs to be achieved. Therefore, the miniaturization of the field effect transistor leads to the reduction in power consumption of a semiconductor device through the reduction in the driving voltage of the field effect transistor.

In this regard, for example, when forming a field effect transistor on an SOI substrate made up of a support substrate, a buried insulating layer formed on the support substrate, and a semiconductor layer formed on the buried insulating layer, the field effect can be enhanced as compared with the case where a field effect transistor is formed on a bulk substrate (semiconductor substrate). This is because a wraparound electric field from the drain is blocked by the buried insulating layer in the field effect transistor formed on the SOI the substrate, and thus the channel formed in semiconductor layer is controlled only by a gate electric field. Accordingly, the “short channel effect” in which the on/off ratio is significantly deteriorated by the drain electric field can be reduced. Note that the improvement in the controllability of the channel by the gate electric field also means that the gate voltage can be reduced. Namely, it means that the reduction in power consumption of the semiconductor device including the field effect transistor can be realized. As described above, it can be seen that the SOI technology is useful from the viewpoint of reducing the power consumption of the semiconductor device. In other words, since the SOI technology is suitable for reducing the driving voltage of the field effect transistor, the miniaturization of the field effect transistor can be advanced by using the SOI technology. Here, the semiconductor device includes a digital circuit and an analog circuit, and the study by the inventors of the present invention has revealed that it is necessary to apply ingenuity for improving the characteristics of the field effect transistor constituting the analog circuit in order to improve the characteristics of the analog circuit particularly when the SOI technology is used for the analog circuit. This point will be described below.

### <Analog Amplifier Circuit>

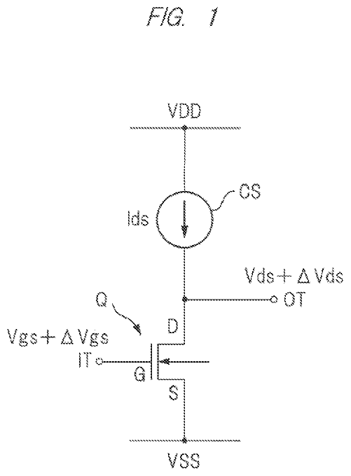

FIG. 1 is a diagram showing an example of an analog amplifier circuit using a field effect transistor and a constant current source. As shown in FIG. 1, the analog amplifier circuit includes, for example, a constant current source CS composed of a current mirror circuit and a field effect transistor Q. Specifically, in the analog amplifier circuit, the constant current source CS and the field effect transistor Q are connected in series between a power supply terminal VDD and a ground terminal VSS. Namely, a drain D of the field effect transistor Q is connected to the constant current source CS, and a source S of the field effect transistor Q is connected to the ground terminal VSS. At this time, a gate electrode G of the field effect transistor Q functions as an input terminal IT of the analog amplifier circuit, and a connection node between the drain D of the field effect transistor Q and the constant current source CS functions as an output terminal OT of the analog amplifier circuit. In the analog amplifier circuit thus configured, first, as shown in FIG. 1, a gate voltage Vgs is applied to the gate electrode G of the field effect transistor Q, and a drain voltage Vds is applied to the drain D of the field effect transistor Q. In this case, the field effect transistor is configured to operate in a saturation region. Then, an input voltage ΔVgs is applied to the gate electrode G of the field effect transistor Q that is in an on operation. Thereby, the drain current of the field effect transistor Q changes, but since the constant current source CS is connected in series with the field effect transistor Q in the analog amplifier circuit shown in FIG. 1, the drain current of the field effect transistor Q is controlled to be constant by the constant current source CS even when the input voltage ΔVgs is applied to the field effect transistor Q. Specifically, even when the input voltage ΔVgs is applied to the field effect transistor Q, the drain voltage Vds of the field effect transistor Q is changed to Vds+ΔVds by the constant current source CS so that the drain current of the field effect transistor Q becomes constant. As a result, the drain voltage (Vds+ΔVds) is output from the output terminal OT of the analog amplifier circuit. As described above, in the analog amplifier circuit shown in FIG. 1, the drain voltage (output voltage) output from the output terminal OT changes by ΔVds in accordance with the input voltage ΔVgs input to the input terminal IT. At this time, the gain of the analog amplifier circuit is improved as the ΔVds corresponding to the change amount of the drain voltage (output voltage) becomes larger with respect to the input voltage ΔVgs.

### <Importance of Saturation Characteristics>

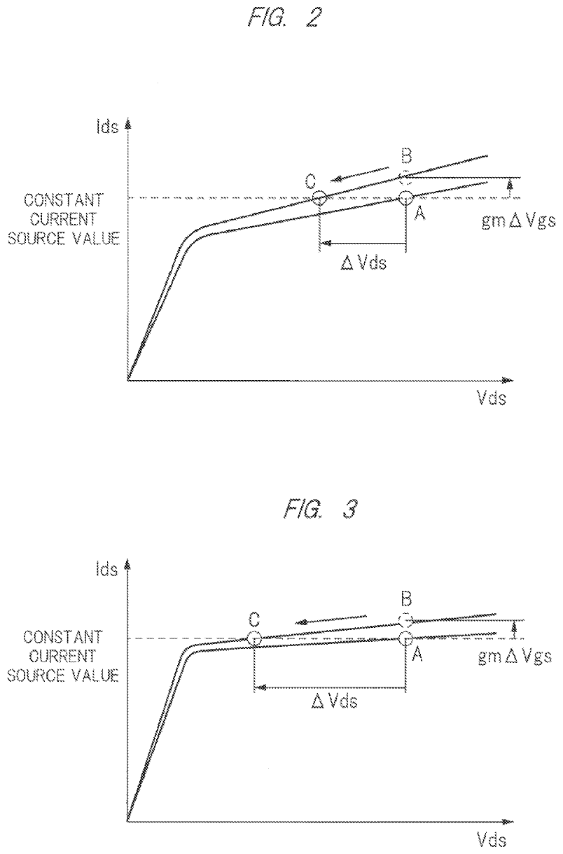

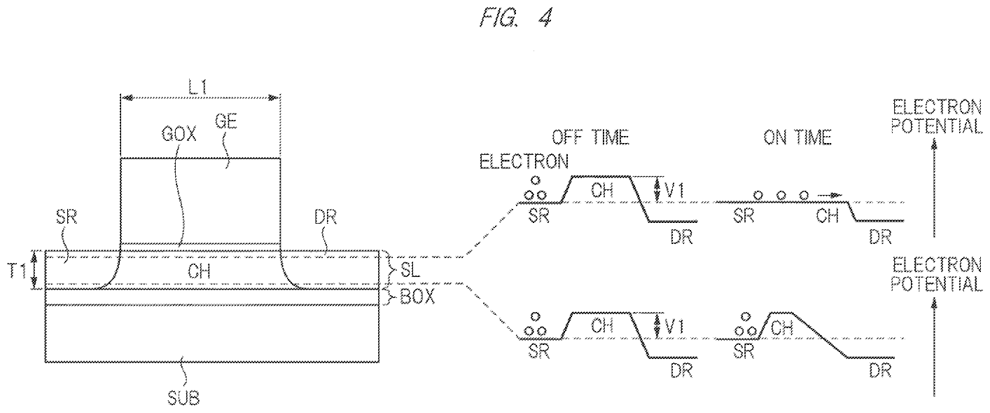

Next, the fact that the gain (amplification factor) of the analog amplifier circuit shown in FIG. 1 depends on the saturation characteristics of the field effect transistor Q will be described with reference to FIG. 2 and FIG. 3. In FIG. 2, first, the field effect transistor Q is assumed to be in the state “A” in the saturation region. Then, the input voltage ΔVgs is applied to the gate electrode of the field effect transistor Q in the state “A”. Here, assuming that the transfer conductance is gm, the drain current of the field effect transistor Q changes by gm×ΔVgs, and the field effect transistor Q changes from the state “A” to the state “B”. At this time, since the constant current source CS is connected in series with the field effect transistor Q in the analog amplifier circuit shown in FIG. 1, the drain current of the field effect transistor Q is controlled to be constant by the constant current source CS. As a result, in FIG. 2, the field effect transistor Q changes from the state “B” to the state “C”. As described above, in the analog amplifier circuit shown in FIG. 1, when the input voltage ΔVgs is applied to the gate electrode of the field effect transistor Q, the field effect transistor Q changes from the state “A” to the state “C”, so that the drain voltage of the field effect transistor Q changes by ΔVds. Namely, in the analog amplifier circuit shown in FIG. 1, when the input voltage ΔVgs is input to the input terminal IT, the output voltage changes by ΔVds in accordance with the input voltage ΔVgs. At this time, the gain of the analog amplifier circuit shown in FIG. 1 is defined by ΔVds/ΔVgs. Therefore, the gain of the analog amplifier circuit shown in FIG. 1 increases as the change (ΔVds) in the output voltage in accordance with the input voltage ΔVgs becomes larger. In this regard, FIG. 3 shows a characteristic in which the change in the drain current Ids with respect to the change in the drain voltage Vds is smaller in the saturation region of the field effect transistor Q as compared with FIG. 2. In this case, as can be seen by the comparison between FIG. 2 and FIG. 3, the change in the drain voltage (ΔVds) becomes large when the same input voltage ΔVgs is applied to the field effect transistor Q. In other words, in the saturation region of the field effect transistor Q, the smaller the change in the drain current Ids with respect to the change in the drain voltage Vds becomes, the larger the gain of the analog amplifier circuit shown in FIG. 1 becomes. Also, the fact that the change in the drain current Ids is small with respect to the change in the drain voltage Vds in the saturation region of the field effect transistor Q means that the saturation characteristics of the field effect transistor Q are favorable. Therefore, it can be seen that the gain of the analog amplifier circuit shown in FIG. 1 depends on the saturation characteristics of the field effect transistor Q, and the gain of the analog amplifier circuit shown in FIG. 1 becomes larger as the saturation characteristics of the field effect transistor Q become more favorable. This indicates that it is important to improve the saturation characteristics of the field effect transistor Q used in the analog amplifier circuit. For example, in the field effect transistor used in the digital circuit, the switching operation of being turned on in the saturation region and turned off in the subthreshold region is just required, and thus the characteristics of the digital circuit are not so much affected by the slope of the saturation characteristics of the field effect transistor. On the other hand, since the gain of the analog amplifier circuit largely depends on the slope of the saturation characteristics of the field effect transistor Q in the above-described analog amplifier circuit, the saturation characteristics of the field effect transistor Q greatly affect the characteristics of the analog amplifier circuit. Therefore, in the field effect transistor Q used in the analog amplifier circuit, it is important to improve the saturation characteristics of the field effect transistor Q from the viewpoint of improving the characteristics of the analog amplifier circuit typified by the gain.

### <Necessity of Applying Ingenuity for Improving Saturation Characteristics>

As described above, it is important to improve the saturation characteristics of the field effect transistor in order to improve the characteristics of the analog amplifier circuit typified by the gain. Also, since the inventors of the present invention have found out the new knowledge that it is necessary to apply ingenuity to the thickness of the semiconductor layer constituting the SOI substrate in order to improve the saturation characteristics of the field effect transistor which directly lead to the improvement of the characteristics of the analog amplifier circuit in the field effect transistor formed on the SOI substrate, the new knowledge will be described below.

First, when the gate length of the gate electrode of the field effect transistor formed on the SOI substrate is large, the necessity of applying ingenuity to the thickness of the semiconductor layer constituting the SOI substrate in order to improve the saturation characteristics of the field effect transistor decreases. For example, FIG. 4 is a diagram illustrating a mechanism in which deterioration of saturation characteristics of the field effect transistor is less likely to occur when the field effect transistor having the gate electrode GE with a large gate length L1 is formed on the thick semiconductor layer SL with a thickness T1 formed on the buried insulating layer BOX. On the left side of FIG. 4, the SOI substrate is made up of the support substrate SUB, the buried insulating layer BOX formed on the support substrate SUB, and the semiconductor layer (silicon layer, SOI layer) SL formed on the buried insulating layer BOX. Also, a source region SR of the field effect transistor and a drain region DR of the field effect transistor are formed in the semiconductor layer SL of the SOI substrate so as to be separated from each other. At this time, the semiconductor region sandwiched between the source region SR and the drain region DR serves as a channel formation region CH, and a gate insulating film GOX of the field effect transistor is formed on the channel formation region CH. Further, the gate electrode GE of the field effect transistor is formed on the gate insulating film GOX.

Note that the gate length L1 is a length of the gate electrode GE along a direction from one of the source region SR and the drain region DR to the other as shown in FIG. 4.

Here, on the right side of FIG. 4, the electron potential in the region near the front surface of the channel formation region CH in contact with the gate insulating film GOX and the electron potential in the region near the back surface of the channel formation region CH in contact with the buried insulating layer BOX are shown. First, when focusing on the electron potential in the region near the front surface of the channel formation region CH in contact with the gate insulating film GOX, a potential barrier V1 is formed between the source region SR and the channel formation region CH at the time of the off operation of the field effect transistor. Similarly, when focusing on the electron potential in the region near the back surface of the channel formation region CH in contact with the buried insulating layer BOX, the potential barrier V1 is formed also between the source region SR and the channel formation region CH at the time of the off operation of the field effect transistor.

Next, since an inversion layer is formed near the front surface of the channel formation region CH in contact with the gate insulating film GOX at the time of the on operation of the field effect transistor, the potential barrier V1 formed between the source region SR and the channel formation region CH disappears in the region near the front surface of the channel formation region CH in contact with the gate insulating film GOX, and electrons flow from the source region SR to the drain region DR through the channel formation region CH. On the other hand, since the inversion layer is not formed in the region near the back surface of the channel formation region CH in contact with the buried insulating layer BOX, the potential barrier V1 formed between the source region SR and the channel formation region CH is almost maintained in the region near the back surface of the channel formation region CH in contact with the buried insulation layer BOX, so that electrons do not flow from the source region SR to the drain region DR through the channel formation region CH. At this time, in the field effect transistor having the gate electrode GE with the large gate length L1, the potential barrier V1 formed between the source region SR and the channel formation region CH is less likely to be affected by the drain voltage (Vds) applied to the drain region DR because of the large gate length L1. As a result, in the saturation region of the field effect transistor having the gate electrode GE with the large gate length L1, the increase in drain current at the position distant from the gate electrode GE is suppressed, so that the saturation characteristics of the field effect transistor are improved. In other words, in the field effect transistor having the gate electrode GE with the large gate length, the necessity of applying ingenuity to the thickness of the semiconductor layer constituting the SOI substrate in order to improve the saturation characteristics of the field effect transistor decreases.

On the other hand, when the gate length of the gate electrode GE of the field effect transistor is shortened due to the miniaturization of the field effect transistor, the short channel effect becomes apparent. Namely, the miniaturization of the field effect transistor means that the driving voltage (drain voltage and gate voltage) of the field effect transistor is lowered according to the scaling law. However, since the short channel effect becomes apparent when the gate length of the gate electrode GE is shortened, even if the driving voltage (drain voltage and gate voltage) is simply lowered based on the scaling law, it is difficult to improve the saturation characteristics of the miniaturized field effect transistor. Namely, in the miniaturized field effect transistor with a small gate length, it is necessary to apply ingenuity to the thickness of the semiconductor layer constituting the SOI substrate in order to improve the saturation characteristics of the field effect transistor. This point will be described below.

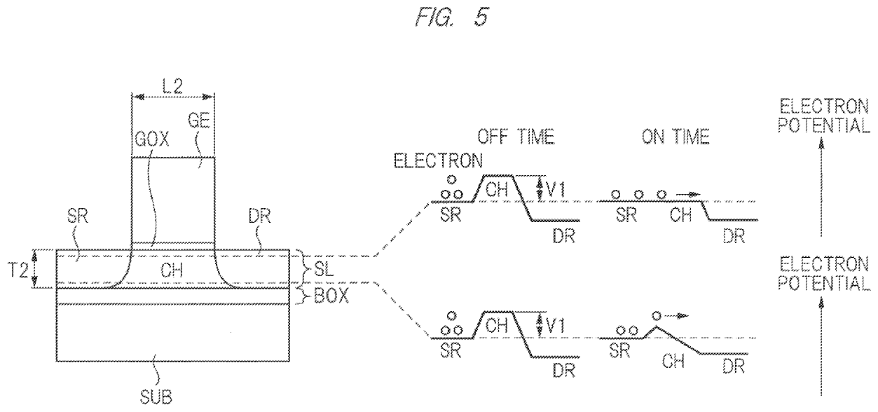

FIG. 5 is a diagram illustrating a mechanism in which deterioration of saturation characteristics occurs when the field effect transistor having the gate electrode GE with a small gate length L2 is formed on the thick semiconductor layer SL with a thickness T2 (for example, larger than 25 nm) formed on the buried insulating layer BOX. On the left side of FIG. 5, a schematic cross-sectional structure of the field effect transistor is shown. On the left side of FIG. 5, the SOI substrate is made up of the support substrate SUB, the buried insulating layer BOX formed on the support substrate SUB, and the semiconductor layer (silicon layer, SOI layer) SL formed on the buried insulating layer BOX. Further, the source region SR of the field effect transistor and the drain region DR of the field effect transistor are formed in the semiconductor layer SL of the SOI substrate so as to be separated from each other. At this time, the semiconductor region sandwiched between the source region SR and the drain region DR serves as the channel formation region CH, and the gate insulating film GOX of the field effect transistor is formed on the channel formation region CH. Further, the gate electrode GE of the field effect transistor is formed on the gate insulating film GOX.

Note that the gate length L2 is a length of the gate electrode GE along a direction from one of the source region SR and the drain region DR to the other as described above.

Here, on the right side of FIG. 5, the electron potential in the region near the front surface of the channel formation region CH in contact with the gate insulating film GOX and the electron potential in the region near the back surface of the channel formation region CH in contact with the buried insulating layer BOX are shown. First, when focusing on the electron potential in the region near the front surface of the channel formation region CH in contact with the gate insulating film GOX, the potential barrier V1 is formed between the source region SR and the channel formation region CH at the time of the off operation of the field effect transistor. Similarly, when focusing on the electron potential in the region near the back surface of the channel formation region CH in contact with the buried insulating layer BOX, the potential barrier V1 is formed also between the source region SR and the channel formation region CH at the time of the off operation of the field effect transistor.

Next, since an inversion layer is formed near the front surface of the channel formation region CH in contact with the gate insulating film GOX at the time of the on operation of the field effect transistor, the potential barrier V1 formed between the source region SR and the channel formation region CH disappears in the region near the front surface of the channel formation region CH in contact with the gate insulating film GOX, and electrons flow from the source region SR to the drain region DR through the channel formation region CH. On the other hand, since the inversion layer is not formed in the region near the back surface of the channel formation region CH in contact with the buried insulating layer BOX, it is supposed that the potential barrier V1 formed between the source region SR and the channel formation region CH is almost maintained in the region near the back surface of the channel formation region CH in contact with the buried insulation layer BOX, so that electrons do not flow from the source region SR to the drain region DR through the channel formation region CH. However, even if the driving voltage (drain voltage and gate voltage) is simply lowered based on the scaling law in the miniaturized field effect transistor, the potential barrier formed between the source region SR and the channel formation region CH is likely to be affected by the drain voltage applied to the drain region DR because of the small gate length L2 of the gate electrode GE. In this manner, when the field effect transistor having the gate electrode GE with the small gate length L2 is formed on the thick semiconductor layer SL with the thickness T2 formed on the buried insulating layer BOX, the potential barrier formed between the source region SR and the channel formation region CH is greatly affected by the drain voltage at a position distant from the gate electrode GE, and is thus reduced (short channel effect). Consequently, at the time of the on operation of the field effect transistor, the electron potential in the region near the back surface of the channel formation region CH in contact with the buried insulating layer BOX becomes lower than the electron potential in the region near the front surface of the channel formation region CH in contact with the gate insulating film GOX. As a result, in the saturation region of the field effect transistor having the gate electrode GE with the small gate length L2, the drain current increases at a position distant from the gate electrode GE, so that the saturation characteristics of the field effect transistor are deteriorated. In other words, even if the driving voltage (drain voltage and gate voltage) is simply lowered based on the scaling law in the field effect transistor having the gate electrode GE with the small gate length L2, the short channel effect becomes apparent and thus the saturation characteristics of the field effect transistor are deteriorated. Namely, in order to improve the saturation characteristics of the field effect transistor, the necessity of applying ingenuity to the thickness of the semiconductor layer SL constituting the SOI substrate increases.

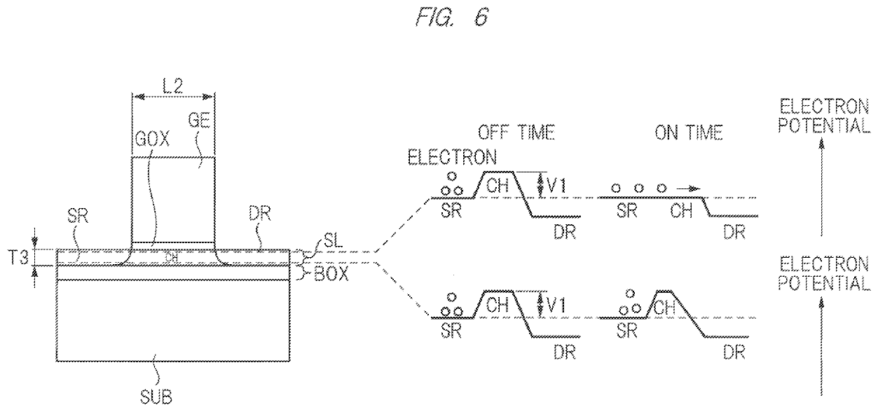

FIG. 6 is a diagram illustrating a mechanism in which the deterioration of saturation characteristics is less likely to occur when the field effect transistor is formed on the thin semiconductor layer SL with a thickness T3 (<T2) formed on the buried insulating layer BOX. On the left side of FIG. 6, a schematic cross-sectional structure of the field effect transistor is shown. On the left side of FIG. 6, the SOI substrate is made up of the support substrate SUB, the buried insulating layer BOX formed on the support substrate SUB, and the semiconductor layer (silicon layer, SOI layer) SL formed on the buried insulating layer BOX. Further, the source region SR of the field effect transistor and the drain region DR of the field effect transistor are formed in the semiconductor layer SL of the SOI substrate so as to be separated from each other. At this time, the semiconductor region sandwiched between the source region SR and the drain region DR serves as the channel formation region CH, and the gate insulating film GOX of the field effect transistor is formed on the channel formation region CH. Further, the gate electrode GE of the field effect transistor is formed on the gate insulating film GOX.

Here, on the right side of FIG. 6, the electron potential in the region near the front surface of the channel formation region CH in contact with the gate insulating film GOX and the electron potential in the region near the back surface of the channel formation region CH in contact with the buried insulating layer BOX are shown. First, when focusing on the electron potential in the region near the front surface of the channel formation region CH in contact with the gate insulating film GOX, the potential barrier V1 is formed between the source region SR and the channel formation region CH at the time of the off operation of the field effect transistor. Similarly, when focusing on the electron potential in the region near the back surface of the channel formation region CH in contact with the buried insulating layer BOX, the potential barrier V1 is formed between the source region SR and the channel formation region CH at the time of the off operation of the field effect transistor.

Next, since an inversion layer is formed near the front surface of the channel formation region CH in contact with the gate insulating film GOX at the time of the on operation of the field effect transistor, the potential barrier V1 formed between the source region SR and the channel formation region CH disappears in the region near the front surface of the channel formation region CH in contact with the gate insulating film GOX, and electrons flow from the source region SR to the drain region DR through the channel formation region CH. On the other hand, since the inversion layer is not formed in the region near the back surface of the channel formation region CH in contact with the buried insulating layer BOX, the potential barrier V1 formed between the source region SR and the channel formation region CH is almost maintained in the region near the back surface of the channel formation region CH in contact with the buried insulation layer BOX, so that electrons do not flow from the source region SR to the drain region DR through the channel formation region CH.

Here, when the field effect transistor is formed on the thin semiconductor layer SL with the thickness T3 formed on the buried insulating layer BOX, the junction depth of the drain region DR small because the semiconductor layer SL of the SOI substrate is thin. This means that the amount of charge in the channel formation region CH controlled by the gate electrode GE increases (charge sharing model). In other words, the controllability by the gate electrode GE is improved in the field effect transistor formed on the thin semiconductor layer SL with the thickness T3 formed on the buried insulating layer BOX. Therefore, since the controllability by the gate electrode GE is improved even at a position distant from the gate electrode GE in the field effect transistor formed on the thin semiconductor layer SL with the thickness T3, the influence of the drain voltage (Vds) applied to the drain region DR is reduced. Therefore, when the field effect transistor is formed on the thin semiconductor layer formed on the buried insulating layer BOX, the potential barrier formed between the source region SR and the channel formation region CH is maintained at the position distant from the gate electrode GE. As a result, when the field effect transistor having the gate electrode GE with the small gate length L2 is formed on the thin semiconductor layer SL formed on the buried insulating layer BOX, the increase in the drain current at the position distant from the gate electrode GE is suppressed in the saturation region of the field effect transistor, so that the saturation characteristics of the field effect transistor are improved.

From the above, according to the description of the qualitative mechanism, which is a knowledge newly found by the inventors of the present invention, even if the driving voltage (drain voltage and gate voltage) is lowered based on the scaling law, it is possible to suppress the deterioration of the saturation characteristics of the field effect transistor due to that the short channel effect becomes apparent. Namely, by applying ingenuity to the thickness of the semiconductor layer constituting the SOI substrate, it is possible to suppress the short channel effect from being apparent while miniaturizing the field effect transistor (lower the driving voltage). In other words, according to the description of the qualitative mechanism, which is a knowledge newly found by the inventors of the present invention, it can be seen that the saturation characteristics of the field effect transistor which directly lead to the improvement of the characteristics of the analog amplifier circuit can be improved in the field effect transistor formed on the SOI substrate and having the gate electrode with the small gate length. Thus, the technical idea in the first embodiment in which ingenuity is applied to the thickness of the semiconductor layer constituting the SOI substrate will be described below.

### <Device Structure>

FIG. 7 is a schematic cross-sectional view showing a device structure of the semiconductor device according to the first embodiment. FIG. 7 shows an n-channel field effect transistor formation region R1 and a p-channel field effect transistor formation region R2, and an n-channel field effect transistor On is formed in the n-channel field effect transistor formation region R1 and a p-channel field effect transistor Qp is formed in the p-channel field effect transistor formation region R2.

First, the device structure of the n-channel field effect transistor Qn will be described. In FIG. 7, element isolation regions STI are formed in the SOI substrate made up of the support substrate SUB, the buried insulating layer BOX, and the semiconductor layer SL, and the n-channel field effect transistor Qn is formed in the n-channel field effect transistor formation region R1 defined by the element isolation regions STI. This n-channel field effect transistor Qn includes a source region SR1 formed in the semiconductor layer SL of the SOI substrate and a drain region DR1 formed in the semiconductor layer SL of the SOI substrate so as to be separated from the source region SR1. At this time, as shown in FIG. 7, the source region SR1 is composed of an n-type semiconductor region NR and an extension region EX1 which is an n-type semiconductor region having an impurity concentration lower than an impurity concentration of the n-type semiconductor region NR. Similarly, the drain region DR1 is composed of an n-type semiconductor region NR and an extension region EX1 which is an n-type semiconductor region having an impurity concentration lower than an impurity concentration of the n-type semiconductor region NR. Also, the n-channel field effect transistor Qn includes a channel formation region CH1 sandwiched between the source region SR1 and the drain region DR1, a gate insulating film GOX1 formed on the channel formation region CH1, and a gate electrode GE1 formed on the gate insulating film GOX1. Further, sidewall spacers SW are formed on the sidewalls on both sides of the gate electrode GE1. In addition, a silicide film is formed on each of the surface of the gate electrode GE1, the surface of the source region SR1, and the surface of the drain region DR1. An interlayer insulating film IL is formed so as to cover the n-channel field effect transistor Qn thus configured, and a plurality of plugs PLG penetrating the interlayer insulating film IL are formed. One of the plurality of plugs PLG is electrically connected to the source region SR1, and another one of the plurality of plugs PLG is electrically connected to the drain region DR1. Further, a p-type well PWL made of a p-type semiconductor region is formed in the support substrate SUB located below the semiconductor layer SL of the SOI substrate on which the n-channel field effect transistor Qn is formed, and an n-type well NWL made of an n-type semiconductor region is formed in the support substrate SUB of the SOI substrate so as to include the p-type well PWL. The buried insulating layer BOX and the semiconductor layer SL formed on a part of the p-type well PWL are removed. At this time, the part of the p-type well PWL is electrically connected to the plug PLG penetrating the interlayer insulating film IL formed on the support substrate SUB, and a silicide film is formed on a surface of the part of the p-type well PWL.

Next, the device structure of the p-channel field effect transistor Qp will be described. In FIG. 7, element isolation regions STI are formed in the SOI substrate made up of the support substrate SUB, the buried insulating layer BOX, and the semiconductor layer SL, and the p-channel field effect transistor Qp is formed in the p-channel field effect transistor formation region R2 defined by the element isolation regions STI. This p-channel field effect transistor Qp includes a source region SR2 formed in the semiconductor layer SL of the SOI substrate and a drain region DR2 formed in the semiconductor layer SL of the SOI substrate so as to be separated from the source region SR2. At this time, as shown in FIG. 7, the source region SR2 is composed of a p-type semiconductor region PR and an extension region EX2 which is a p-type semiconductor region having an impurity concentration lower than an impurity concentration of the p-type semiconductor region PR. Similarly, the drain region DR2 is composed of a p-type semiconductor region PR and an extension region EX2 which is a p-type semiconductor region having an impurity concentration lower than an impurity concentration of the p-type semiconductor region PR. Also, the p-channel field effect transistor Qp includes a channel formation region CH2 sandwiched between the source region SR2 and the drain region DR2, a gate insulating film GOX2 formed on the channel formation region CH2, and a gate electrode GE2 formed on the gate insulating film GOX2. Further, sidewall spacers SW are formed on the sidewalls on both sides of the gate electrode GE2. In addition, a silicide film is formed on each of the surface of the gate electrode GE2, the surface of the source region SR2, and the surface of the drain region DR2. The interlayer insulating film IL is formed so as to cover the p-channel field effect transistor Qp thus configured, and a plurality of plugs PLG penetrating the interlayer insulating film IL are formed. One of the plurality of plugs PLG is electrically connected to the source region SR2, and another one of the plurality of plugs PLG is electrically connected to the drain region DR2. Further, the n-type well NWL made of an n-type semiconductor region is formed in the support substrate SUB located below the semiconductor layer SL of the SOI substrate on which the p-channel field effect transistor Qp is formed. The buried insulating layer BOX and the semiconductor layer SL formed on a part of the n-type well NWL are removed. At this time, the part of the n-type well NWL is electrically connected to the plug PLG penetrating the interlayer insulating film IL formed on the support substrate SUB, and a silicide film is formed on the part of the n-type well NWL.

As described above, the n-channel field effect transistor Qn according to the first embodiment is formed in the n-channel field effect transistor formation region R1 of the SOI substrate, and the p-channel field effect transistor Qp according to the first embodiment is formed in the p-channel field effect transistor formation region R2 of the SOI substrate.

Here, the n-channel field effect transistor Qn including the gate insulating film GOX1, the gate electrode GE1, the channel formation region CH1, the source region SR1, and the drain region DR1 is a component of an analog circuit. This analog circuit includes at least one or more n-channel field effect transistors Qn, and the thickness of the semiconductor layer SL of the SOI substrate is 2 nm or more and 24 nm or less. At this time, for example, the gate length of the gate electrode GE1 is 100 nm or less. In this case, the absolute value of the difference between the potential applied to the source region SR1 of the n-channel field effect transistor Qn and the potential applied to the drain region DR1 is 0.4 V or more and 1.2 V or less. At this time, the condition of the lower limit value of 0.4 V or more is determined by the condition of using the field effect transistor in the saturation region, while the condition of the upper limit value of 1.2 V or less is determined by the condition that the field effect transistor does not cause the punch through. Further, the impurity concentration a conductivity-type of impurity in the channel formation region CH1 of the n-channel field effect transistor On is higher than 1×10¹⁷/cm³ and 1×10¹⁸/cm³ or lower.

From the viewpoint of improving the saturation characteristics, more desirably, the thickness of the semiconductor layer SL of the SOI substrate is, for example, 8 nm or more and 12 nm or less. For example, the gate length of the gate electrode GE1 is 150 nm or less. In this case, the absolute value of the difference between the potential applied to the source region SR1 of the n-channel field effect transistor Qn and the potential applied to the drain region DR1 is 0.4 V or more and 1.6 V or less. At this time, the condition of the lower limit value of 0.4 V or more is determined by the condition of using the field effect transistor in the saturation region, while the condition of the upper limit value of 1.6 V or less is determined by the condition that the field effect transistor does not cause the punch through. Further, the impurity concentration of a conductivity-type impurity in the channel formation region CH1 of the n-channel field effect transistor Qn is 1×10¹⁷/cm³ or lower.

Similarly, the p-channel field effect transistor Qp including the gate insulating film GOX2, the gate electrode GE2, the channel formation region CH2, the source region SR2, and the drain region DR2 is also a component of the analog circuit. This analog circuit includes at least one or more p-channel field effect transistors Qp, and the thickness of the semiconductor layer SL of the SOI substrate is 2 nm or more and 24 nm or less. At this time, for example, the gate length of the gate electrode GE2 is 100 nm or less. In this case, the absolute value of the difference between the applied to the source region SR2 of the p-channel field effect transistor Qp and the potential applied to the drain region DR2 is 0.4 V or more and 1.2 V or less. At this time, the condition of the lower limit value of 0.4 V or more is determined by the condition of using the field effect transistor in the saturation region, while the condition of the upper limit value of 1.2 V or less is determined by the condition that the field effect transistor does not cause the punch through. Further, the impurity concentration of a conductivity-type impurity in the channel formation region CH2 of the p-channel field effect transistor Qp is higher than 1×10¹⁷/cm³ and 1×10¹⁸/cm³ or lower.

From the viewpoint of improving the saturation characteristics, more desirably, the thickness of the semiconductor layer SL of the SOI substrate is, for example, 8 nm or more and 12 nm or less. For example, the gate length of the gate electrode GE2 is 150 nm or less. In this case, the absolute value of the difference between the potential applied to the source region SR2 of the p-channel field effect transistor Qp and the potential applied to the drain region DR2 is 0.4 V or more and 1.6 V or less. At this time, the condition of the lower limit value of 0.4 V or more is determined by the condition of using the field effect transistor in the saturation region, while the condition of the upper limit value of 1.6 V or less is determined by the condition that the field effect transistor does not cause the punch through. Further, the impurity concentration of a conductivity-type impurity in the channel formation region CH2 of the p-channel field effect transistor Qp is 1×10¹⁷/cm³ or lower.

In addition, the thickness of the buried insulating layer BOX of the SOI substrate is 10 nm or more and 20 nm or less, and the p-type well PWL which is located below the channel formation region CH1 of the n-channel field effect transistor Qn and is in contact with the buried insulating layer BOX is formed in the support substrate SUB of the SOI substrate. On the other hand, the n-type well NWL which is located below the channel formation region CH2 of the p-channel field effect transistor Qp and is in contact with the buried insulating layer BOX is also formed in the support substrate SUB of the SOI substrate.

### Features of First Embodiment

### <<First Feature>>

Next, the features of the first embodiment will be described. The first feature of the first embodiment is that the thickness of the semiconductor layer of the SOI which the substrate on field effect transistor constituting the analog circuit is formed is 2 nm or more and 24 nm or less. This makes it possible to improve the saturation characteristics of the field effect transistor constituting the analog circuit. As a result, the circuit characteristics of the analog circuit typified by the gain can be improved.

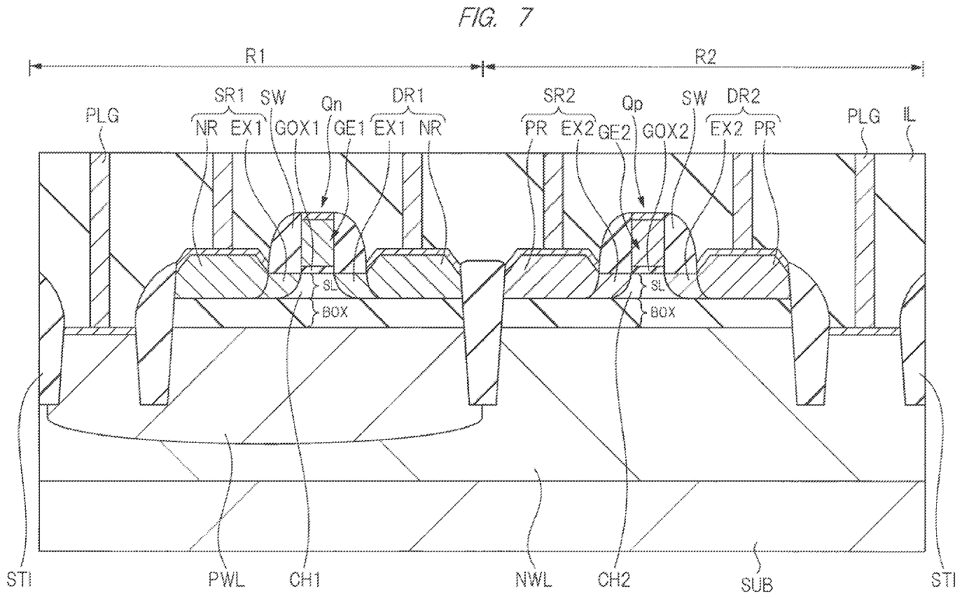

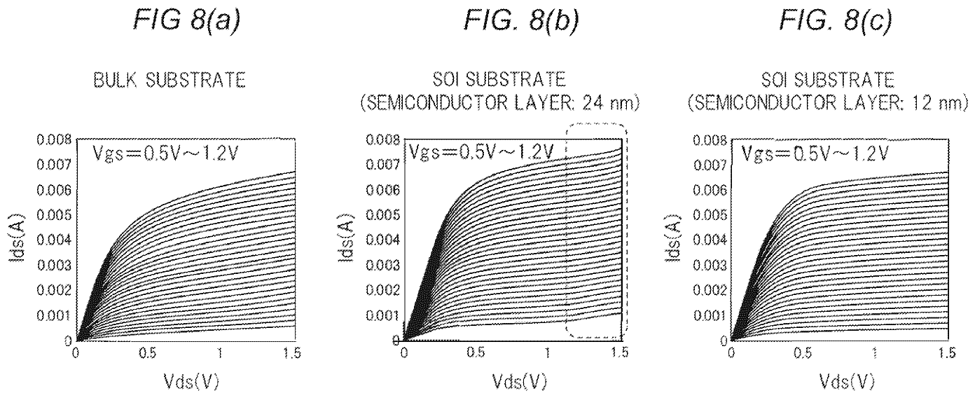

For example, FIG. 8(a) is a graph a showing relationship between the drain voltage (Vds) and the drain current (Ids) when a field effect transistor having a gate electrode with a gate length of 60 nm is formed on a bulk substrate and the gate voltage in the range of 0.5 V to 1.2 V is applied to the gate electrode. Also, FIG. 8(b) is a graph showing a relationship between the drain voltage (Vds) and the drain current (Ids) when a field effect transistor having a gate electrode with a gate length of 60 nm is formed on an SOI substrate having a semiconductor layer (silicon layer) with a thickness of 24 nm and the gate voltage in the range of 0.5 V to 1.2 V is applied to the gate electrode. Further, FIG. 8(c) is a graph showing a relationship between the drain voltage (Vds) and the drain current (Ids) when a field effect transistor having a gate electrode with a gate length of 60 nm is formed on an SOI substrate having a semiconductor layer (silicon layer) with a thickness of 12 nm and the gate voltage in the range of 0.5 V to 1.2 V is applied to the gate electrode.

First, it can be seen from FIG. 8(a) to FIG. 8(c) that the saturation characteristics of the field effect transistor whose relationship between the drain voltage and the drain current is shown in the graph of FIG. 8(c) are the best. Further, the saturation characteristics of the field effect transistor whose relationship between the drain voltage and the drain current is shown in the graph of FIG. 8(b) are inferior to the saturation characteristics of the field effect transistor whose relationship between the drain voltage and the drain current is shown in the graph of FIG. 8(c). On the other hand, in the region of the drain voltage of 1.2 V or lower, the saturation characteristics of the field effect transistor whose relationship between the drain voltage and the drain current is shown in the graph of FIG. 8(b) are superior to the saturation characteristics of the field effect transistor whose relationship between the drain voltage and the drain current is shown in the graph of FIG. 8(a). Accordingly, it can be said that the saturation characteristics of a field effect transistor are superior when the field effect transistor is formed on an SOI substrate having a semiconductor layer with a thickness of 12 nm as compared with the case where a field effect transistor is formed on an SOI substrate having a semiconductor layer with a thickness of 24 nm and the case where a field effect transistor is formed on a bulk substrate. Namely, in order to improve the saturation characteristics of a field effect transistor miniaturized to have the gate electrode with the gate length of about 60 nm, it is desirable to form the field effect transistor on the SOI substrate having a semiconductor layer with a thickness of 12 nm.

The basic idea understood from the above results is that the saturation characteristics of a field effect transistor can be more easily improved when a miniaturized field effect transistor in which the short channel effect becomes apparent is formed on an SOI substrate as compared with the case where it is formed on a bulk substrate, and the saturation characteristics of a field effect transistor can be more easily improved as the thickness of the semiconductor layer (silicon layer) of the SOI substrate on which the field effect transistor is formed becomes smaller. In particular, in an analog circuit in which the saturation characteristics of the field effect transistor are important from the viewpoint of improving the circuit characteristics, it is effective that the field effect transistor constituting the analog circuit is formed on an SOI substrate having a semiconductor layer (silicon layer) with a small thickness.

The basic idea in the first embodiment like this can be implemented by adopting the first feature of the first embodiment that the thickness of a semiconductor layer of an SOI substrate on which the field effect transistor constituting an analog circuit is formed is set to 2 nm or more and 24 nm or less. In particular, by applying the first feature of the first embodiment to the field effect transistor in which the gate length of the gate electrode is miniaturized to 150 nm or less and the short channel effect is likely to become apparent, the deterioration of the saturation characteristics of the field effect transistor can be effectively suppressed. As a result, according to the first feature of the first embodiment, it is possible to improve the saturation characteristics that greatly affect the circuit characteristics of the analog circuit, while miniaturizing the field effect transistor constituting the analog circuit.

In particular, since an SOI substrate has a substrate structure more suitable for realizing low-voltage driving (drain voltage and gate voltage) of a field effect transistor as compared with a bulk substrate, the field effect transistor can be miniaturized when the field effect transistor is formed on the SOI substrate. Namely, since the low-voltage driving of the field effect transistor can be realized when the field effect transistor constituting an analog circuit is formed on the SOI substrate, the field effect transistor can be miniaturized. At this time, it is conceivable that the short channel effect is likely to become apparent if the field effect transistor is miniaturized, and the saturation characteristics which greatly affect the circuit characteristics of the analog circuit are likely to be deteriorated. Regarding this point, by adopting the first feature of the first embodiment, it is possible to improve the saturation characteristics of the field effect transistor even in the case of the miniaturized field effect transistor in which the short channel effect is likely to become apparent. As described above, according to the first feature of the first embodiment, it is possible to improve the saturation characteristics that greatly affect the circuit characteristics of the analog circuit, while miniaturizing the field effect transistor constituting the analog circuit.

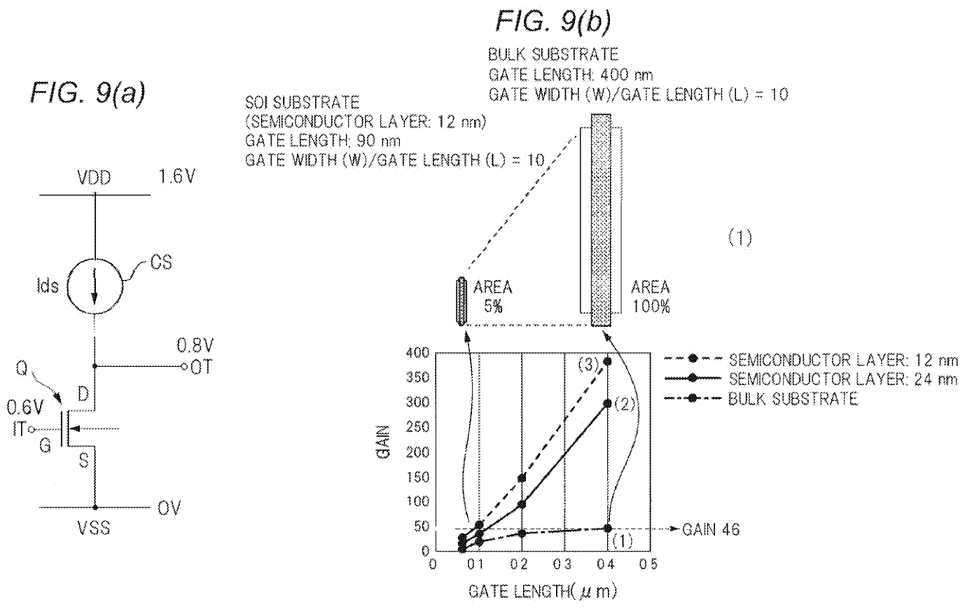

FIG. 9(a) is a circuit diagram in which specific voltages applied to the analog amplifier circuit described in FIG. 1 when the analog amplifier circuit is driven at low voltage are written. In FIG. 9(a), 1.6 V is applied to the power supply terminal VDD, and 0 V is applied to the ground terminal VSS. Also, in FIG. 9(a), 0.6 V is applied to the gate electrode G (input terminal IT) of the field effect transistor Q, and 0.8 V is applied to the drain D (output terminal OT) of the field effect transistor Q. In particular, since the field effect transistor is formed on the SOI substrate and the low-voltage driving of the field effect transistor is possible in the first embodiment, the analog amplifier circuit can be operated even by the low voltage shown in FIG. 9(a).

Here, in FIG. 9(a), when an input voltage (input signal voltage) is applied in the state where 0.6 V (bias reference point) is being applied to the gate electrode of the field effect transistor Q, an output voltage (output signal voltage) of, for example, 0.8 V±0.5 V is output with 0.8 V as a bias reference point from the output terminal OT connected to the drain D of the field effect transistor Q. At this time, if the field effect transistor having the current-voltage characteristics shown in FIG. 8(c) is adopted as the field effect transistor Q, since the field effect transistor shown in FIG. 8(c) does not cause the punch through when the drain voltage of up to 1.6 V is applied, the punch through is not caused and favorable saturation characteristics are obtained within the range of the condition shown in FIG. 9(a). Thus, it can be seen that the field effect transistor having the current-voltage characteristics shown in FIG. 8(c) is suitable for operating the analog amplifier circuit at low voltage as shown in FIG. 9(a).

On the other hand, if the field effect transistor having the current-voltage characteristics shown in FIG. 8(b) is adopted as the field effect transistor Q, since the field effect transistor shown in FIG. 8(b) does not cause the punch through when the drain voltage of up to 1.2 V is applied, the punch through is not caused and favorable saturation characteristics are obtained when it is used so as to output the output voltage (output signal voltage) of 0.8 V+0.4 V within the range of the condition shown in FIG. 9(a). Thus, it can be seen that the field effect transistor having the current-voltage characteristics shown in FIG. 8(b) can be used when operating the analog amplifier circuit at low voltage as shown in FIG. 9(a), though limited.

FIG. 9(b) is a graph showing a relationship between the gate length of the gate electrode of the field effect transistor and the gain in the analog amplifier circuit shown in FIG. 9(a). Here, a line graph (1) shown in FIG. 9(b) shows a relationship between the gate length and the gain in the case where the analog amplifier circuit shown in FIG. 9(a) is configured by using the field effect transistor formed on the bulk substrate. Also, a line graph (2) shown in FIG. 9(b) shows a relationship between the gate length and the gain in the case where the analog amplifier circuit shown in FIG. 9(a) is configured by using the field effect transistor formed on the SOI substrate having the semiconductor layer (silicon layer) with a thickness of 24 nm. In addition, a line graph (3) shown in FIG. 9(b) shows a relationship between the gate length and the gain in the case where the analog amplifier circuit shown in FIG. 9(a) is configured by using the field effect transistor formed on the SOI substrate having the semiconductor layer (silicon layer) with a thickness of 12 nm. In FIG. 9(b), the change in the gain when the gate length is changed is remarkably large in the line graph (2) showing the relationship between the gate length and the gain when the field effect transistor formed on the SOI substrate having the semiconductor layer (silicon layer) with a thickness of 24 nm is used, as compared with the line graph (1) showing the relationship between the gate length and the gain when the field effect transistor formed on the bulk substrate is used. Also, the change in the gain when the gate length: changed is more remarkably large in the line graph (3) showing the relationship between the gate length and the gain when the field effect transistor formed on the SOI substrate having the semiconductor layer (silicon layer) with a thickness of 12 nm is used, as compared with the line graph (1) showing the relationship between the gate length and the gain when the field effect transistor formed on the bulk substrate is used. This is because the saturation characteristics of the field effect transistor formed on the SOI substrate having the semiconductor layer (silicon layer) with a thickness of 24 nm and the saturation characteristics of the field effect transistor formed on the SOI substrate having the semiconductor layer (silicon layer) with a thickness of 12 nm are more favorable than the saturation characteristics of the field effect transistor formed on the bulk substrate. Therefore, from the results shown in FIG. 9(b), when the gate length of the gate electrode is made the same, the gain of the analog amplifier circuit can be increased when the field effect transistor formed on the SOI substrate having the semiconductor layer with a thickness of 24 nm and the field effect transistor formed on the SOI substrate having the semiconductor layer with a thickness of 12 nm are used, as compared with the case where the field effect transistor formed on the bulk substrate is used. Namely, the circuit characteristics of the analog amplifier circuit can be improved when the field effect transistor formed on the SOI substrate having the semiconductor layer (silicon layer) with a thickness of 24 nm and the field effect transistor formed on the SOI substrate having the semiconductor layer (silicon layer) with a thickness of 12 nm are used, as compared with the case where the field effect transistor formed on the bulk substrate is used. Accordingly, it can be seen that the circuit characteristics of the analog amplifier circuit can be improved when the thickness of the semiconductor layer of the SOI substrate on which the field effect transistor constituting the analog amplifier circuit is formed is 24 nm or less. However, when the thickness of the semiconductor layer of the SOI substrate on which the field effect transistor constituting the analog amplifier circuit is formed is less than 2 nm, it becomes difficult to manufacture the SOI substrate itself. Accordingly, it is possible to obtain a remarkable effect that the circuit characteristics of the analog amplifier circuit can be improved while maintaining the manufacturing easiness of the SOI substrate itself when the thickness of the semiconductor layer of the SOI substrate on which the field effect transistor constituting the analog amplifier circuit is formed is 2 nm or more and 24 nm or less.

From another viewpoint, for example, when the gain of the analog amplifier circuit is designed to be “46” by using the field effect transistor formed on the bulk substrate in FIG. 9(b), the gate length of the gate electrode needs to be 400 nm (0.4 μm) from the line graph (1). On the other hand, when the gain of the analog amplifier circuit is designed to be “46” by using the field effect transistor formed on the SOI substrate having the semiconductor layer (silicon layer) with a thickness of 12 nm in FIG. 9(b), it is sufficient if the gate length of the gate electrode is 90 nm (0.09 μm) from the line graph (3). Therefore, this means that the plane size of the field effect transistor in the case where the analog amplifier circuit is configured by using the field effect transistor formed on the SOI substrate having the semiconductor layer (silicon layer) with a thickness of 12 nm can be reduced to about 5% of the plane size of the field effect transistor in the case where the analog amplifier circuit is configured by using the field effect transistor formed on the bulk substrate. As described above, when the analog amplifier circuit shown in FIG. 9(a) is configured by using the field effect transistor according to the first embodiment, the area occupied by the field effect transistor can be significantly reduced, and thus, the size of the semiconductor device including the analog amplifier circuit can be reduced. In other words, by adopting the first feature of the first embodiment, the circuit characteristics of the analog amplifier circuit can be improved when the plane size of the field effect transistor according to the first embodiment is made equal to the plane size of the field effect transistor formed on the bulk substrate. Meanwhile, by adopting the first feature of the first embodiment, the size of the semiconductor device including the analog amplifier circuit can be reduced when the gain of the analog amplifier circuit configured of the field effect transistor according to the first embodiment is made equal to the gain of the analog amplification circuit configured of the field effect transistor formed on the bulk substrate. Note that, since the current to drive the circuit can be reduced if the size of the semiconductor device can be reduced, it is possible to reduce the power consumption of the semiconductor device.

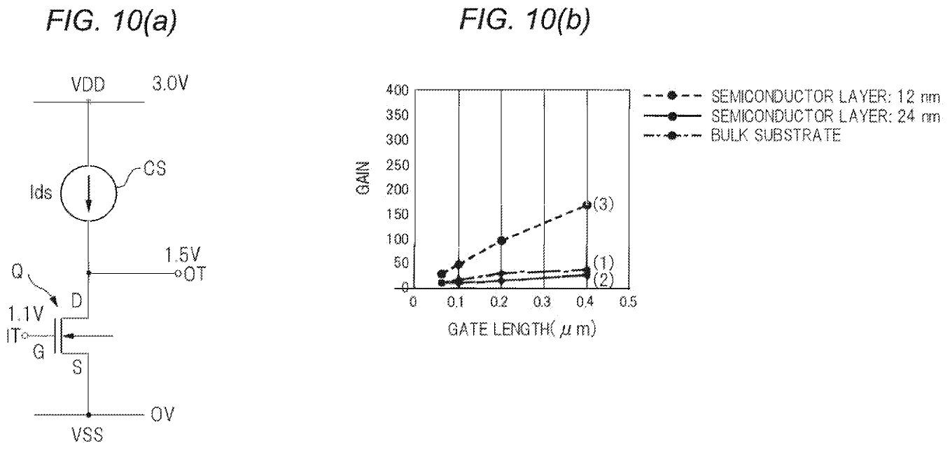

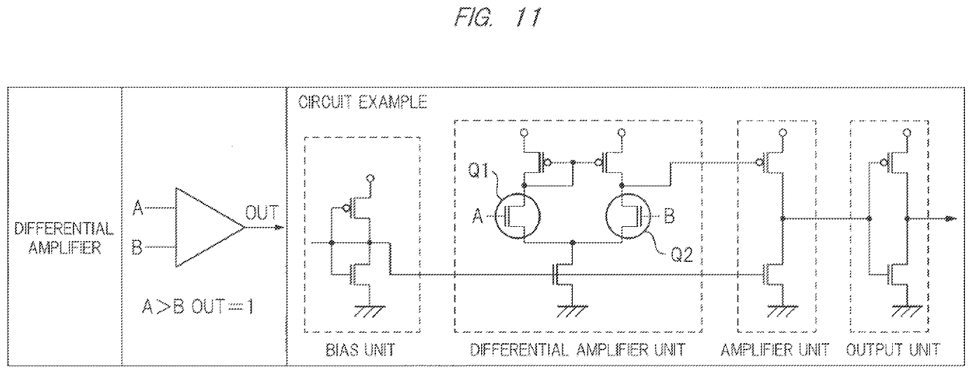

Subsequently, FIG. 10(a) is a circuit diagram in which specific voltages applied to the analog amplifier circuit described in FIG. 1 when the analog amplifier circuit is driven at higher voltage than the operation condition of FIG. 9(a) are written. In FIG. 10(a), 3.0 V is applied to the power supply terminal VDD, and 0 V is applied to the ground terminal VSS. Also, in FIG. 10(a), 1.1 V is applied to the gate electrode G (input terminal IT) of the field effect transistor Q, and 1.5V is applied to the drain D (output terminal OT) of the field effect transistor Q.

Here, in FIG. 10(a), when an input voltage (input signal voltage) is applied in the state where 1.1 V (bias reference point) is being applied to the gate electrode of the field effect transistor Q, an output voltage (output signal voltage) of, for example, 1.5 V±1.0 V is output with 1.5 V as a bias reference point from the output terminal OT connected to the drain D of the field effect transistor Q. At this time, if the field effect transistor having the current-voltage characteristics shown in FIG. 8(c) is adopted as the field effect transistor Q, since the field effect transistor shown in FIG. 8(c) does not cause the punch through when the drain voltage of up to 1.6 V is applied but causes the punch through when the drain voltage is higher than that, the punch through is not caused and favorable saturation characteristics are obtained when it is used so as to output the output voltage (output signal voltage) of 1.5 V±0.1 V within the range of the condition shown in FIG. 10(a). Accordingly, the field effect transistor having the current-voltage characteristics shown in FIG. 8(c) can be used when operating the analog amplifier circuit at high voltage as shown in FIG. 10(a), though limited.

On the other hand, if the field effect transistor having the current-voltage characteristics shown in FIG. 8(b) is adopted as the field effect transistor Q, the field effect transistor shown in FIG. 8(b) causes the punch through when the drain voltage higher than 1.2 V is applied. Accordingly, the field effect transistor having the current-voltage characteristics shown in FIG. 8(b) cannot be used when operating the analog amplifier circuit at high voltage as shown in FIG. 10(a).

FIG. 10(b) is a graph showing a relationship between the gate length of the gate electrode of the field effect transistor and the gain in the analog amplifier circuit shown in FIG. 10(a). Here, a line graph (1) shown in FIG. 10(b) shows a relationship between the gate length and the gain in the case where the analog amplifier circuit shown in FIG. 10(a) is configured by using the field effect transistor formed on the bulk substrate. Also, a line graph (2) shown in FIG. 10(b) shows a relationship between the gate length and the gain in the case where the analog amplifier circuit shown in FIG. 10(a) is configured by using the field effect transistor formed on the SOI substrate having the semiconductor layer (silicon layer) with a thickness of 24 nm. In addition, a line graph (3) shown in FIG. 10(b) shows a relationship between the gate length and the gain in the case where the analog amplifier circuit shown in FIG. 10(a) is configured by using the field effect transistor formed on the SOI substrate having the semiconductor layer (silicon layer) with a thickness of 12 nm.

In FIG. 10(b), unlike FIG. 9(b), the line graph (2) showing the relationship between the gate length and the gain when the field effect transistor formed on the SOI substrate having the semiconductor layer (silicon layer) with a thickness of 24 nm is used is equivalent to the line graph (1) showing the relationship between the gate length and the gain when the field effect transistor formed on the bulk substrate is used. This is because, as shown in a region surrounded by a broken line in FIG. 8(b), the field effect transistor formed on the SOI substrate having the semiconductor layer (silicon layer) with a thickness of 24 nm causes the punch through when the drain voltage exceeds 1.0 V, and the resistance (rds) between the source region and the drain region decreases. Namely, this is because, when the resistance between the source region and the drain region is “rds” and the transfer conductance is “gm”, the gain of the analog amplifier circuit is represented by “rds”×“gm” and thus the gain of the analog amplifier circuit is reduced if the punch through is caused and the resistance (rds) between the source region and the drain region decreases.

On the other hand, the change in the gain when the gate length is changed is remarkably large in the line graph (3) showing the relationship between the gate length and the gain when the field effect transistor formed on the SOI substrate having the semiconductor layer (silicon layer) with a thickness of 12 nm is used, as compared with the line graph (1) showing the relationship between the gate length and the gain when the field effect transistor formed on the bulk substrate is used. This is because the saturation characteristics of the field effect transistor formed on the SOI substrate having the semiconductor layer (silicon layer) with a thickness of 12 nm are more favorable than the saturation characteristics of the field effect transistor formed on the bulk substrate over a wide range of drain voltage as shown in FIG. 8(c).

Therefore, from the viewpoint of improving the gain of the analog amplifier circuit over a wide range of drain voltage, it is desirable that the thickness of the semiconductor layer of the SOI substrate on which the field effect transistor constituting the analog amplifier circuit is formed is 12 nm or less. On the other hand, since the resistance (rds) between the source region and the drain region becomes excessively high if the thickness of the semiconductor layer of the SOI substrate is less than 8 nm, it is desirable that the thickness of the semiconductor layer of the SOI substrate on which the field effect transistor constituting the analog amplifier circuit is formed is 8 nm or more. From the above, particularly from the viewpoint of improving the circuit characteristics of the analog amplifier circuit over a wide range of drain voltage, it is desirable that the thickness of the semiconductor layer of the SOI substrate on which the field effect transistor constituting the analog amplifier circuit is formed is 8 nm or more and 12 nm or less.

### <<Second Feature>>

Next, the second feature of the first embodiment is that the impurity concentration of the conductivity-type impurity in the channel formation region of the field effect transistor formed on the SOI substrate is 1×10¹⁸/cm³ or lower, preferably 3×10¹⁷/cm³, and more preferably 1×10¹⁷/cm³ or lower. Specifically, the second feature of the first embodiment is that the impurity concentration of a p-type impurity (boron or the like) contained in the channel formation region CH1 of the n-channel field effect transistor On shown in, for example, FIG. 7 is 1×10¹⁸/cm³ or lower, preferably 1×10¹⁷/cm³ or lower. Similarly, the second feature of the first embodiment is that the impurity concentration of an n-type impurity (phosphorus or arsenic) contained in the channel formation region CH2 of the p-channel field effect transistor Qp shown in, for example, FIG. 7 is 1×10¹⁸/cm³ or lower, preferably 1×10¹⁷/cm³ or lower. Thus, for example, when the analog circuit includes a plurality of n-channel field effect transistors Qn, variation in the impurity concentration of the p-type impurity contained in the channel formation regions CH1 in the plurality of n-channel field effect transistors Qn can be reduced. For example, a differential amplifier may be included as a component of the analog circuit, and the differential amplifier is configured to include a plurality of n-channel field effect transistors On having the same characteristics.

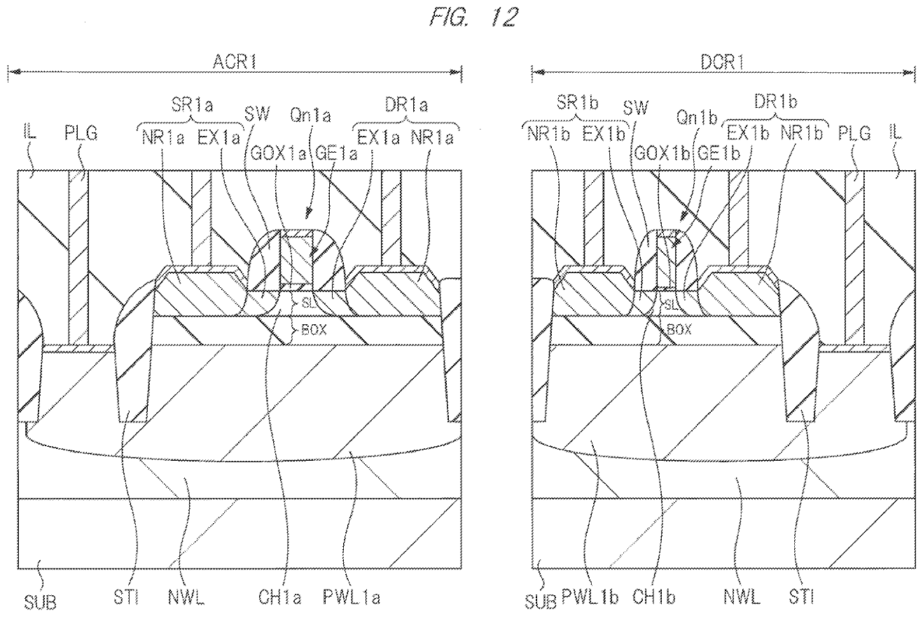

Specifically, FIG. 11 is a diagram schematically showing a function and a circuit configuration of a differential amplifier. For example, the differential amplifier includes an input terminal “A” and an input terminal “B”, and it has a function of outputting “1” from an output terminal “OUT” when an input signal input to the input terminal “A” is larger than an input signal input to the input terminal “B” and outputting “0” from the output terminal “OUT” in the other cases. As shown in FIG. 11, the differential amplifier having such a function is configured of a bias unit, a differential amplifier unit, an amplifier unit, and an output unit. Also, when focusing on the differential amplifier unit, the gate electrode of the n-channel field effect transistor Q1 is connected to the input terminal “A”, and the gate electrode of the n-channel field effect transistor Q2 is connected to the input terminal “B”. At this time, the n-channel field effect transistor Q1 and the n-channel field effect transistor Q2 are required to have the same characteristics. Namely, it is desired that the threshold voltage of the n-channel field effect transistor Q1 and the threshold voltage of the n-channel field effect transistor Q2 are the same. This is because “0” needs to be output from the output terminal “OUT” when the input signal input to the input terminal “A” and the input signal input to the input terminal “B” are equal to each other. Namely, this is because, if the threshold voltage of the n-channel field effect transistor Q1 is different from the threshold voltage of the n-channel field effect transistor Q2, a malfunction may occur due to the variation in the threshold voltage even though the input signal input to the input terminal “A” and the input signal input to the input terminal “B” are equal to each other. Then, for example, in order to make the threshold voltage of the n-channel field effect transistor Q1 and the threshold voltage of the n-channel field effect transistor Q2 equal to each other, it is necessary to make the impurity concentration of the p-type impurity contained in the channel formation region of the n-channel field effect transistor Q1 and the impurity concentration of the p-type impurity contained in the channel formation region of the n-channel field effect transistor Q2 equal to each other. In this regard, if the impurity concentration of the p-type impurity contained in the channel formation region is increased, the variation in the impurity concentration is increased, so that the variation in the threshold voltage of the n-channel field effect transistor Q1 and the threshold voltage of the n-channel field effect transistor Q2 is increased. Therefore, in the first embodiment, the impurity concentration of the p-type impurity contained in the channel formation region of the n-channel field effect transistor Q1 is set to 1×10¹⁸/cm³ or lower, preferably, 1×10¹⁷/cm³ or lower. Similarly, in the first embodiment, the impurity concentration of the p-type impurity contained in the channel formation region of the n-channel field effect transistor Q2 is set to 1×10¹⁸/cm³ or lower, preferably, 1×10¹⁷/cm³ or lower. Thus, according to the second feature of the first embodiment, for example, the variation in the impurity concentration of the p-type impurity contained in the channel formation regions of the n-channel field effect transistor Q1 and the n-channel field effect transistor Q2 included in the differential amplifier can be reduced. Thus, according to the second feature of the first embodiment, the variation in the threshold voltage of the n-channel field effect transistor Q1 and the threshold voltage of the n-channel field effect transistor Q2 can be reduced, so that the operational reliability of the differential amplifier can be improved.

### <<Side Effect of Second Feature>>

However, if the second feature of the first embodiment that the impurity concentration of the conductivity-type impurity in the channel formation region of the field effect transistor formed on the SOI substrate is set to 1×10¹⁸/cm³ or lower, preferably, 1×10¹⁷/cm³ or lower is adopted, the side effect that the threshold voltage of the field effect transistor is lowered occurs. Such a decrease in the threshold voltage of the field effect transistor leads to an increase in the subthreshold leakage current, so that the power consumption of the semiconductor device is increased. Therefore, in order to suppress the increase in the subthreshold leakage current, it is necessary to suppress the decrease in the threshold voltage of the field effect transistor, and in order to maintain the threshold voltage of the field effect transistor formed on the SOI substrate, it is necessary to increase the impurity concentration of the conductivity-type impurity contained in the channel formation region of the field effect transistor. Thus, in the first embodiment, an ingenuity is applied to suppress the side effect of the decrease in the threshold voltage induced by adopting the second feature. Namely, in the first embodiment, as means for suppressing the increase in the subthreshold leakage current, an ingenuity to adopt alternative means is applied without relying on the means of increasing the impurity concentration of the conductivity-type impurity contained in the channel formation region of the field effect transistor.

### <<Measure 1 for Suppressing Side Effect>>

The basic idea of the measure 1 for suppressing the side effect is that a well region is formed in a part of the support substrate of the SOI substrate, which is located below the channel formation region of the field effect transistor formed on the SOI substrate and is in contact with the buried insulating layer, and a back gate voltage is applied to the well region. As a result, even if the second feature of the first embodiment that the impurity concentration of the conductivity-type impurity contained in the channel formation region of the field effect transistor is set to 1×10¹⁸/cm³ or lower, preferably 1×10¹⁷/cm³ or lower is adopted, the increase in the subthreshold leakage current of the field effect transistor can be suppressed by the back gate voltage applied to the well region. Specifically, for example, in FIG. 7, the p-type well PWL is formed in a part, which is located below the channel formation region CH1 of the n-channel field effect transistor Q1 formed on the SOI substrate and is in contact with the buried insulating layer BOX, and a back gate voltage having a negative bias is applied to the p-type well PWL. As a result, the potential of the channel formation region CH1 of the n-channel field effect transistor Q1 is raised by the back gate voltage, so that the increase in the subthreshold leakage current of the n-channel field effect transistor Q1 can be suppressed. In particular, in the first embodiment, the back gate voltage can be continuously applied from the non-operation time to the operation time of the n-channel field effect transistor Q1.

As an example other than the case where the back gate voltage is continuously applied from the non-operation time to the operation time, the back gate voltage may be applied only during the non-operation time and the back gate voltage may not be applied during the operation time. This makes it possible to suppress the leakage current when not in use, and to increase the driving current in a low threshold state during the operation time.

In addition, it is also possible to apply the back gate voltage during the non-operation time and to apply or not apply the back gate voltage during the operation time in a time-division manner. Further, it is also possible to apply the back gate voltage during the operation time and to apply the back gate voltage only to a certain region and not to apply it to the other region during the non-operation time.

Similarly, for example, in FIG. 7, the n-type well NWL is formed in a part, which is located below the channel formation region CH2 of the p-channel field effect transistor Q2 formed on the SOI substrate and is in contact with the buried insulating layer BOX, and a back gate voltage having a positive bias is applied to the n-type well NWL. As a result, the increase in the subthreshold leakage current of the p-channel field effect transistor Q2 can be suppressed by the back gate voltage. In particular, in the first embodiment, the back gate voltage can be continuously applied from the non-operation time to the operation time of the p-channel field effect transistor Q2.

As an example other than the case where the back gate voltage is continuously applied from the non-operation time to the operation time, the back gate voltage may be applied only during the non-operation time and the back gate voltage may not be applied during the operation time. This makes it possible to suppress the leakage current when not in use, and to increase the driving current in a low threshold state during the operation time.

In addition, it is also possible to apply the back gate voltage during the non-operation time and to apply or not apply the back gate voltage during the operation time in a time-division manner. Further, it is also possible to apply the back gate voltage during the operation time and to apply the back gate voltage only to a certain region and not to apply it to the other region during the non-operation time.

Here, in the present embodiment, the SOTB technology in which the thickness of the buried insulating layer BOX is 10 nm or more and 20 nm or less is adopted. Thus, in the measure 1 of the first embodiment, unnecessary leakage current can be suppressed by controlling the potential of the channel of the field effect transistor by the back gate voltage applied to the well region.

### <<Measure 2 for Suppressing Side Effect>>

Next, the basic idea of the measure 2 for suppressing the side effect is that the decrease in the threshold voltage of the field effect transistor is suppressed by using the so-called “Fermi level pinning”. “Fermi level pinning” is a phenomenon described below. For example, when focusing on an n-channel field effect transistor, an n-type polysilicon film is used for a gate electrode. At this time, when an element such as hafnium or aluminum having a dielectric constant higher than a dielectric constant of a silicon oxide film is added to a gate insulating film, the level Fermi of the n-type polysilicon film shifts. Specifically, the Fermi level of the n-type polysilicon film is usually located near the conduction band, but when hafnium or aluminum is added to the gate insulating film, the Fermi level of the n-type polysilicon film shifts toward the valence band. This means that the threshold voltage of the n-channel field effect transistor increases. Normally, when the Fermi level of the n-type polysilicon film constituting the gate electrode is located near the conduction band, the threshold voltage as designed can be ensured, but when the above-described “Fermi level pinning” occurs, the threshold voltage of the n-channel field effect transistor shifts from the design value to the higher value. Therefore, an incentive to suppress “Fermi level pinning” usually works.

However, the inventors of the present invention have reversed the way of thinking, and the side effect of the decrease in the threshold voltage caused when the above-described second feature of the first embodiment is adopted is suppressed by intentionally causing the “Fermi level pinning” by focusing on the point that the threshold voltage of the n-channel field effect transistor increases when “Fermi level pinning” occurs. Namely, in the first embodiment, the gate insulating film of the n-channel field effect transistor is configured to contain an element typified by hafnium or aluminum having a dielectric constant higher than a dielectric constant of a silicon oxide film as the measure 2 for suppressing the side effect. As a result, according to the first embodiment, “Fermi level pinning” can be intentionally caused, so that the decrease in the threshold voltage of the n-channel field effect transistor can be effectively suppressed.

Similarly, for example, when focusing on a p-channel field effect transistor, a p-type polysilicon film is used for a gate electrode. At this time, when an element having a dielectric constant higher than a dielectric constant of a silicon oxide film is added to a gate insulating film, the Fermi level of the p-type polysilicon film shifts (“Fermi level pinning”). Specifically, the Fermi level of the p-type polysilicon film is usually located near the valence band, but when an element having a dielectric constant higher than a dielectric constant of a silicon oxide film is added to the gate insulating film, the Fermi level of the p-type polysilicon film shifts toward the conduction band. Therefore, also in the p-channel field effect transistor, “Fermi level pinning” can be intentionally caused, so that the decrease in the threshold voltage of the p-channel field effect transistor can be effectively suppressed.

### Second Embodiment

In the second embodiment, an example in which a field effect transistor constituting an analog circuit and a field effect transistor constituting a digital circuit are formed on the same SOI substrate will be described.

### <Difference in Characteristics Required for Field Effect Transistors>

The characteristics required for the field effect transistor constituting the analog circuit are different from the characteristics required for the field effect transistor constituting the digital circuit. Specifically, the field effect transistor constituting the analog circuit is required to have good saturation characteristics, a high withstand voltage between a source and a drain, and a high withstand voltage of a gate insulating film. On the other hand, since switching of the field effect transistor constituting the digital circuit is frequently performed in the digital circuit, the field effect transistor constituting the digital circuit is required to have high-speed switching characteristics. As described above, the required characteristics are different between the field effect transistor constituting the analog circuit and the field effect transistor constituting the digital circuit. Accordingly, the device structure of the field effect transistor constituting the analog circuit is necessarily different from the device structure of the field effect transistor constituting the digital circuit. Hereinafter, the device structures of the field effect transistor constituting the analog circuit and the field effect transistor constituting the digital circuit formed on the same SOI substrate will be described.

### <Device Structure>

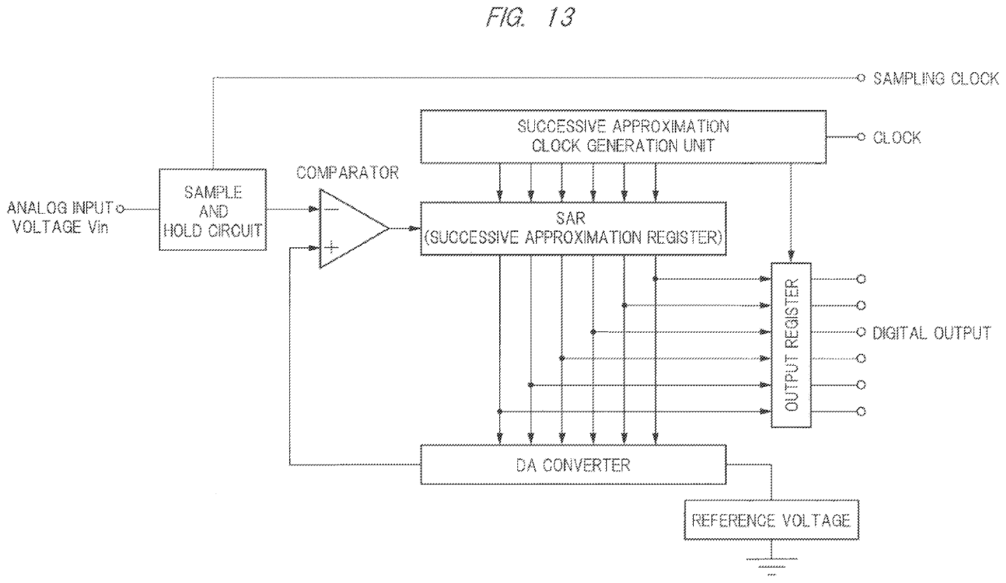

FIG. 12 is a cross-sectional view showing device structures of a plurality of field effect transistors according to the second embodiment. Specifically, in FIG. 12, an n-channel field effect transistor Qn1a constituting an analog circuit is formed in an analog circuit formation region ACR1, and an n-channel field effect transistor Qn1b constituting a digital circuit is formed in a digital circuit formation region DCR1. Note that the analog circuit includes not only the n-channel field effect transistor Qn1a but also a p-channel field effect transistor as a component and the digital circuit includes not only the n-channel field effect transistor Qn1b but also a p-channel field effect transistor as a component, but the p channel field effect transistors are omitted in FIG. 12. Here, the thickness of the the SOI semiconductor layer (silicon layer) SL of substrate is 2 nm or more and 24 nm or less.

<<Device Structure of n-Channel Field Effect Transistor Qn1a>>

In FIG. 12, the n-channel field effect transistor Qn1a is formed in the analog circuit formation region ACR1 of the SOI substrate. The n-channel field effect transistor On1a includes a source region SR1a formed in the semiconductor layer (silicon layer) SL of the SOI substrate and a drain region DR1a formed in the semiconductor layer (silicon layer) SL of the SOI substrate so as to be separated from the source region SR1a. At this time, the source region SR1a is composed of an n-type semiconductor region NR1a and an extension region EX1a having an impurity concentration lower than an impurity concentration lower of the n-type semiconductor region NR1a. Similarly, the drain region DRla is also composed of an n-type semiconductor region NR1a and an extension region EX1a having an impurity concentration lower than an impurity concentration of the n-type semiconductor region NR1a. Also, the n-channel field effect transistor Qn1a includes a channel formation region CH1a sandwiched between the source region SR1a and the drain region DRla, a gate insulating film GOX1a formed on the channel formation region CH1a, and a gate electrode GE1a formed on the gate insulating film GOX1a. Here, sidewall spacers SW are formed on the sidewalls on both sides of the gate electrode GE1a. On the other hand, in the support substrate SUB of the SOI substrate, a p-type well PWL1a which is located below the channel formation region CH1a of the n-channel field effect transistor Qn1a and is in contact with the buried insulating layer BOX is formed. This p-type well PWL1a is configured so that, for example, a back gate voltage having a negative bias can be applied thereto. In this manner, the n-channel field effect transistor Qn1a according to the second embodiment is formed in the analog circuit formation region ACR1 of the SOI substrate.

<<Device Structure of n-Channel Field Effect Transistor Qn1b>>

Next, in FIG. 12, the n-channel field effect transistor Qn1b is formed in the digital circuit formation region DCR1 of the SOI substrate. The n-channel field effect transistor Qn1b includes a source region SR1b formed in the semiconductor layer (silicon layer) SL of the SOI substrate and a drain region DR1b formed in the semiconductor layer (silicon layer) SL of the SOI substrate so as to be separated from the source region SR1b. At this time, the source region SR1b is composed of an n-type semiconductor region NR1b and an extension region EX1b having an impurity concentration lower than an impurity concentration of the n-type semiconductor region NR1b. Similarly, the drain region DR1b is also composed of an n-type semiconductor region NR1b and an extension region EX1b having an impurity concentration lower than an impurity concentration of the n-type semiconductor region NR1b. Also, the n-channel field effect transistor Qn1b includes a channel formation region CH1b sandwiched between the source region SR1b and the drain region DR1b, a gate insulating film GOX1b formed on the channel formation region CH1b, and a gate electrode GE1b formed on the gate insulating film GOX1b. Here, sidewall spacers SW are formed on the sidewalls on both sides of the gate electrode GE1b. On the other hand, in the support substrate SUB of the SOI substrate, a p-type well PWL1b which is located below the channel formation region CH1b of the n-channel field effect transistor Qn1b and is in contact with the buried insulating layer BOX is formed. This p-type well PWL1b is configured so that, for example, a back gate voltage having a negative bias can be applied thereto. In this manner, the n-channel field effect transistor Qn1b according to the second embodiment is formed in the digital circuit formation region DCR1 of the SOI substrate.

### <<Difference>>

The n-channel field effect transistor Qn1a and the n-channel field effect transistor Qn1b configured as described above are different in device structure due to the difference in characteristics required for the analog circuit and the digital circuit, respectively. Hereinafter, differences between the n-channel field effect transistor Qn1a and the n-channel field effect transistor Qn1b will be described.

First, the first difference is that the dielectric withstand voltage between the source region SR1a and the drain region DR1a in the n-channel field effect transistor Qn1a is higher than the dielectric withstand voltage between the source region SR1b and the drain region DR1b in the n-channel field effect transistor Qn1b. This is because the analog circuit is required to have higher dielectric withstand voltage than the digital circuit. Therefore, as shown in FIG. 12, in the second embodiment, the gate length of the gate electrode GE1a of the n-channel field effect transistor Qn1a is larger than the gate length of the gate electrode GE1b of n-channel field effect transistor Qn1b.

Subsequently, the second difference is that the dielectric withstand voltage of the gate insulating film GOX1a in the n-channel field effect transistor Qn1a is higher than the dielectric withstand voltage of the gate insulating film GOX1b in the n-channel field effect transistor Qn1b. This is because the analog circuit is required to have higher dielectric withstand voltage than the digital circuit. Therefore, as shown in FIG. 12, in the second embodiment, the thickness of the gate insulating film GOX1a of the n-channel field effect transistor Qn1a is larger than the thickness of the gate insulating film GOX1b of the n-channel field effect transistor Qn1b.

Next, the third difference is that high-speed switching characteristics are required for the n-channel field effect transistor Qn1b constituting the digital circuit. Thus, the n-channel field effect transistor Qn1b constituting the digital circuit is required to have a large current drivability. Therefore, the threshold voltage of the n-channel field effect transistor Qn1b constituting the digital circuit needs to be lower than the threshold voltage of the n-channel field effect transistor Qn1a constituting the analog circuit. As an example of realizing the third difference, the constituent material of the conductor film constituting the gate electrode GE1a of the n-channel field effect transistor On1a and the constituent material of the conductor film constituting the gate electrode GE1b of the n-channel field effect transistor Qn1b can be made different from each other. In this manner, the work function of the gate electrode GE1a of the n-channel field effect transistor Qn1a and the work function of the gate electrode GE1b of the n-channel field effect transistor Qn1b can be made different from each other. As a result, the threshold voltage of the n-channel field effect transistor Qn1b constituting the digital circuit can be made different the threshold voltage of the n-channel field effect transistor On1a forming the analog circuit.

### <Circuit Example>

In the semiconductor device according to the second embodiment, the n-channel field effect transistor Qn1a constituting the analog circuit and the n-channel field effect transistor Qn1b constituting the digital circuit are formed on the same SOI substrate. The semiconductor device according to the second embodiment in which the analog circuit and the digital circuit are mixedly present as described above can be applied to, for example, the configuration of an A/D converter composed of the analog circuit and the digital circuit. Hereinafter, the configuration of the A/D converter to which the semiconductor device according to the second embodiment can be applied will be described.

FIG. 13 is a circuit block diagram showing the circuit configuration of the successive approximation A/D converter. In FIG. 13, the successive approximation A/D converter includes a sample and hold circuit for inputting an analog input voltage Vin based on a sampling clock, a comparator for comparing an input voltage sampled and held by the sample and hold circuit with a reference voltage, and a successive approximation clock generation unit for generating a successive approximation clock based on the clock. Further, the successive approximation A/D converter includes a successive approximation register (SAR), a DA converter, and an output register. For example, the successive approximation A/D converter configured as described above compares a first voltage (for example, FS/2) generated by the DA converter and the input voltage “Vin” sampled and held by the sample and hold circuit by the comparator. Then, when the input voltage is higher than the first voltage (Vin>FS/2), the most significant bit is set to “1”, and when the input voltage is lower than the first voltage (Vin<FS/2), the most significant bit is set to “0”. Thereafter, the DA converter generates a second voltage (FS/2+FS/4), the second voltage and the input voltage are compared by the comparator, and the bit lower by one digit of the most significant bit is determined based on the comparison result. By repeating such an operation, a digital output corresponding to the input voltage is output from the output register. The successive approximation A/D converter operates in this manner.

The successive approximation A/D converter described above includes, for example, an analog circuit typified by the sample and hold circuit and a digital circuit typified by the successive approximation register (SAR). Therefore, the semiconductor device according to the second embodiment in which an analog circuit and a digital circuit are mixedly present can be applied to, for example, the configuration of the successive approximation A/D converter composed of an analog circuit and a digital circuit.

### <Side Effect of Second Feature>

In the semiconductor device according to the second embodiment as well, the second feature of the first embodiment that the impurity concentration of the conductivity-type impurity in the channel formation region CH1a of the n-channel field effect transistor Qn1a formed on the SOI substrate is set to 1×10¹⁸/cm³ or lower, preferably, 1×10¹⁷/cm³ or lower is adopted. Similarly, in the second embodiment, the second feature of the first embodiment that the impurity concentration of the conductivity-type impurity in the channel formation region CH1b of the n-channel field effect transistor Qn1b formed on the SOI substrate is set to 1×10¹⁸/cm³ or lower, preferably, 1×10¹⁷/cm³ or lower is adopted. In this case, as described in the first embodiment, the side effect that the threshold voltage of the field effect transistor is lowered occurs.

### <Measure 1 for Suppressing Side Effect>

The basic idea of the measure 1 for suppressing the side effect is that p-type wells (PWL1a, PWL1b) are formed in parts of the support substrate of the SOI substrate, which are located below the channel formation regions (CH1a, CH1b) of the field effect transistors (n-channel field effect transistor Qn1a, n-channel field effect transistor Qn1b) formed on the SOI substrate and are in contact with the buried insulating layers BOX, and a back gate voltage is applied to the p-type wells (PWL1a, PWL1b). As a result, even if the second feature that the impurity concentration of the conductivity-type impurity contained in the channel formation regions (CH1a, CH1b) of the field effect transistors (n-channel field effect transistor Qn1a, n-channel field effect transistor Qn1b) is set to 1×10¹⁸/cm³ or lower, preferably 1×10¹⁷/cm³ or lower is adopted, the decrease in the threshold voltage of the field effect transistors (n-channel field effect transistor Qn1a, n-channel field effect transistor Qn1b) can be suppressed by the back gate voltage applied to the p-type wells PWL.

### <Measure 2 for Suppressing Side Effect>

Next, the basic idea of the measure 2 for suppressing the side effect is that the decrease in the threshold voltage of the field effect transistor is suppressed by using the so-called “Fermi level pinning” as in the first embodiment. Here, in the second embodiment, for example, the gate insulating film GOX1a of the n-channel field effect transistor Qn1a constituting the analog circuit is configured to contain a material (High-k material) having a dielectric constant higher than a dielectric constant of the silicon oxide film, while the gate insulating film GOX1b of the n-channel field effect transistor Qn1b constituting the digital circuit can be formed of a silicon oxide film. In this case, the threshold voltage of the n-channel field effect transistor Qn1a constituting the analog circuit can be made higher than the threshold voltage of the n-channel field effect transistor Qn1b constituting the digital circuit.

Further, in the digital circuit as well, the gate insulating film GOX1b of the n-channel field effect transistor Qn1b constituting the digital circuit can also be configured to contain a material having a dielectric constant higher than a dielectric constant of the silicon oxide film in order to reduce the subthreshold leakage current in the n-channel field effect transistor Qn1b constituting the digital circuit. At this time, for example, it is desirable that the content of the “High-k material” in the gate insulating film GOX1a of the n-channel field effect transistor Qn1a constituting the analog circuit is made smaller than the content of the “High-k material” in the gate insulating film GOX1b of the n-channel field effect transistor Qn1b constituting the digital circuit. The reason will be described below.

For example, the “Fermi level pinning” is understood as the phenomenon in which, when a “High-k material” typified by hafnium or aluminum is added to the gate insulating film made of a silicon oxide film, fixed charges (oxygen vacancies) are formed in the gate insulating film, so that the distribution of electrons at the interface between the gate insulating film and the gate electrode changes and the Fermi level shifts. Namely, when a “High-k material” is added to the gate insulating film, the fixed charges are formed. Then, when the electrons are captured or released by the fixed charges, the movement of the electrons occurs, and thus the electric noise is generated. Therefore, as the “High-k material” added to the gate insulating film increases, the number of fixed charges formed in the gate insulating film increases. This means that the electrical noise component increases as the “High-k material” added to the gate insulating film increases.

In this regard, the analog circuit is more susceptible to noise than the digital circuit. In particular, in the second embodiment, the low-voltage driving is realized by forming the field effect transistor constituting the analog circuit on an SOI substrate. This means that the signal component in the analog circuit becomes smaller. On the other hand, since the noise component does not decrease even if the low-voltage driving is realized, the S/N ratio (signal/noise ratio) becomes smaller. Then, when the fixed charges formed in the gate insulating film increase, the electrical noise component further increases, which causes the further decrease of the S/N ratio. Therefore, in the second embodiment, the measure of adding a “High-k material” to the gate insulating film is taken in order to suppress the decrease in the threshold voltage of the field effect transistor constituting the analog circuit, while the amount of “High-k material” added to the gate insulating film is minimized. For this reason, in the second embodiment, the content of the “High-k material” in the gate insulating film of the field effect transistor constituting the analog circuit is made smaller than the content of the “High-k material” in the gate insulating film of the field effect transistor constituting the digital circuit. As a result, in the field effect transistor constituting the analog circuit, a remarkable effect that the decrease in the threshold voltage can be suppressed while suppressing the decrease in the S/N ratio can be obtained.

In the foregoing, the invention made by the inventors of the present invention has been concretely described based on the embodiments. However, it is needless to say that the present invention is not limited to the foregoing embodiments and various modifications can be made within the scope of the present invention.

The embodiments described above include the following aspects.

### (Appendix 1)

A semiconductor device comprising:
a support substrate;
an insulating layer formed on the support substrate;
a semiconductor layer formed on the insulating layer;
a first source region formed in the semiconductor layer;
a first drain region formed in the semiconductor layer so as to be separated from the first source region;
a first channel formation region sandwiched between the first source region and the first drain region;
a first gate insulating film formed on the first channel formation region; and
a first gate electrode formed on the first gate insulating film,
wherein a first field effect transistor including the first gate insulating film, the first gate electrode, the first channel formation region, the first source region, and the first drain region is a component of a first analog circuit,
wherein the first analog circuit includes at least one or more the first field effect transistors, and
wherein a thickness of the semiconductor layer is 2 nm or more and 24 nm or less,
the semiconductor device further comprising:
a second source region formed in the semiconductor layer so as to be separated from the first source region and the first drain region;
a second drain region formed in the semiconductor layer so as to be separated from the first source region, the first drain region, and the second source region;
a second channel formation region sandwiched between the second source region and the second drain region;
a second gate insulating film formed on the second channel formation region so as to be separated from the first gate insulating film; and
a second gate electrode formed on the second gate insulating film so as to be separated from the first gate electrode,
wherein a second field effect transistor including the second gate insulating film, the second gate electrode, the second channel formation region, the second source region, and the second drain region is a component of a first digital circuit.

### (Appendix 2)

The semiconductor device according to the appendix 1,
wherein an impurity concentration of a conductivity-type impurity in the second channel formation region is 1×10¹⁷/cm³ or lower,
wherein the first gate insulating film contains a material having a dielectric constant higher than a dielectric constant of a silicon oxide film, and
wherein the second gate insulating film is made of a silicon oxide film.

### (Appendix 3)

The semiconductor device according to the appendix 1,
wherein an impurity concentration of a conductivity-type impurity in the second channel formation region is 1×10¹⁷/cm³ or lower,
wherein the first gate insulating film contains a material having a dielectric constant higher than a dielectric constant of a silicon oxide film,
wherein the second gate insulating film contains a material having a dielectric constant higher than a dielectric constant of a silicon oxide film, and
wherein a content of the material in the first gate insulating film is smaller than a content of the material in the second gate insulating film.

### (Appendix 4)

A semiconductor device comprising:
a support substrate;
an insulating layer formed on the support substrate;
a semiconductor layer formed on the insulating layer;
a first source region formed in the semiconductor layer;
a first drain region formed in the semiconductor layer so as to be separated from the first source region;
a first channel formation region sandwiched between the first source region and the first drain region;
a first gate insulating film formed on the first channel formation region; and
a first gate electrode formed on the first gate insulating film,
a second source region formed in the semiconductor layer so as to be separated from the first source region and the first drain region;
a second drain region formed in the semiconductor layer so as to be separated from the first source region, the first drain region, and the second source region;
a second channel formation region sandwiched between the second source region and the second drain region;
a second gate insulating film formed on the second channel formation region so as to be separated from the first gate insulating film; and
a second gate electrode formed on the second gate insulating film so as to be separated from the first gate electrode,
wherein a first field effect transistor including the first gate insulating film, the first gate electrode, the first channel formation region, the first source region, and the first drain region is a component of an analog circuit of an A/D converter,
wherein a second field effect transistor including the second gate insulating film, the second gate electrode, the second channel formation region, the second source region, and the second drain region is a component of a digital circuit of the A/D converter, and
wherein a thickness of the semiconductor layer is 2 nm or more and 24 nm or less.

### (Appendix 5)

The semiconductor device according to the appendix 4,
wherein a dielectric withstand voltage between the first source region and the first drain region in the first field effect transistor is higher than a dielectric withstand voltage between the second source region and the second drain region in the second field effect transistor.

### (Appendix 6)

The semiconductor device according to the appendix 4,
wherein a thickness of the first gate insulating film is larger than a thickness of the second gate insulating film.

### (Appendix 7)

The semiconductor device according to the appendix 4,
wherein a gate length of the first gate electrode is larger than a gate length of the second gate electrode.

### (Appendix 8)

The semiconductor device according to the appendix 4,
wherein a first conductor film constituting the first gate electrode and a second conductor film constituting the second gate electrode are different in a constituent material.

### REFERENCE SIGNS LIST

BOX buried insulating layer
CH1 channel formation region
CH2 channel formation region
DR1 drain region
DR2 drain region
GE1 gate electrode
GE2 gate electrode
GOX1 gate insulating film
GOX2 gate insulating film
NWL n-type well
PWL p-type well
SR1 source region
SR2 source region
SUB support substrate

1. A semiconductor device comprising:
a support substrate;
an insulating layer formed on the support substrate;
a semiconductor layer formed on the insulating layer;
a first source region formed in the semiconductor layer;
a first drain region formed in the semiconductor layer so as to be separated from the first source region;
a first channel formation region sandwiched between the first source region and the first drain region;
a first gate insulating film formed on the first channel formation region;
a first gate electrode formed on the first gate insulating film;
a second source region formed in the semiconductor layer so as to be separated from the first source region and the first drain region;
a second drain region formed in the semiconductor layer so as to be separated from the first source region, the first drain region, and the second source region;
a second channel formation region sandwiched between the second source region and the second drain region;
a second gate insulating film formed on the second channel formation region so as to be separated from the first gate insulating film; and
a second gate electrode formed on the second gate insulating film so as to be separated from the first gate electrode,
wherein a first field effect transistor including the first gate insulating film, the first gate electrode, the first channel formation region, the first source region, and the first drain region is a component of a first analog circuit,
wherein a second field effect transistor including the second gate insulating film, the second gate electrode, the second channel formation region, the second source region, and the second drain region is a component of a first digital circuit,
wherein the first analog circuit includes at least one or more the first field effect transistors, and
wherein a thickness of the semiconductor layer is 2 nm or more and 24 nm or less.

2. The semiconductor device according to claim 1,
wherein an impurity concentration of a conductivity-type impurity in the second channel formation region is 1×10¹⁷/cm³ or lower,
wherein the first gate insulating film contains a material having a dielectric constant higher than a dielectric constant of a silicon oxide film, and
wherein the second gate insulating film is made of a silicon oxide film.

3. The semiconductor device according to claim 1,
wherein an impurity concentration of a conductivity-type impurity in the second channel formation region is 1×10¹⁷/cm³ or lower,
wherein the first gate insulating film contains a material having a dielectric constant higher than a dielectric constant of a silicon oxide film,
wherein the second gate insulating film contains a material having a dielectric constant higher than a dielectric constant of a silicon oxide film, and
wherein a content of the material in the first gate insulating film is smaller than a content of the material in the second gate insulating film.

4. A semiconductor device comprising:
a support substrate;
an insulating layer formed on the support substrate;
a semiconductor layer formed on the insulating layer;
a first source region formed in the semiconductor layer;
a first drain region formed in the semiconductor layer so as to be separated from the first source region;
a first channel formation region sandwiched between the first source region and the first drain region;
a first gate insulating film formed on the first channel formation region;
a first gate electrode formed on the first gate insulating film;
a second source region formed in the semiconductor layer so as to be separated from the first source region and the first drain region;
a second drain region formed in the semiconductor layer so as to be separated from the first source region, the first drain region, and the second source region;
a second channel formation region sandwiched between the second source region and the second drain region;
a second gate insulating film formed on the second channel formation region so as to be separated from the first gate insulating film; and
a second gate electrode formed on the second gate insulating film so as to be separated from the first gate electrode,
wherein a first field effect transistor including the first gate insulating film, the first gate electrode, the first channel formation region, the first source region, and the first drain region is a component of an analog circuit of an A/D converter,
wherein a second field effect transistor including the second gate insulating film, the second gate electrode, the second channel formation region, the second source region, and the second drain region is a component of a digital circuit of the A/D converter, and
wherein a thickness of the semiconductor layer is 2 nm or more and 24 nm or less.

5. The semiconductor device according to claim 4, wherein a dielectric withstand voltage between the first source region and the first drain region in the first field effect transistor is higher than a dielectric withstand voltage between the second source region and the second drain region in the second field effect transistor.

6. The semiconductor device according to claim 4, wherein a thickness of the first gate insulating film is larger than a thickness of the second gate insulating film.

7. The semiconductor device according to claim 4, wherein a gate length of the first gate electrode is larger than a gate length of the second gate electrode.

8. The semiconductor device according to claim 4, wherein a material of a first conductor film composing the first gate electrode and a material of a second conductor film composing the second gate electrode are different from each other.
